(19) United States
(12) Patent Application Publication
(10) Pub. No.: US 2011/0013659 A1
(43) Pub. Date: Jan. 20, 2011

(54) SEMICONDUCTOR LASER DEVICE AND METHOD OF MANUFACTURING THE SAME

(75) Inventors: Kunio Takeuchi, Kyoto (JP); Yasumitsu Kunoh, Tottori (JP); Masayuki Hata, Osaka (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi, Osaka (JP)

(21) Appl. No.: 12/919,847

(22) PCT Filed: Feb. 25, 2009
(86) PCT No.: PCT/JP2009/053326

§ 371 Date: Aug. 27, 2010

(30) Foreign Application Priority Data
Feb. 29, 2008 (JP) 2008-049659

(51) Int. Cl. H01S 5/028; H01L 21/30

(52) U.S. Cl. 372/45.01; 438/29; 257/E21.211

(57) ABSTRACT

A semiconductor laser device having a cladding layer in the vicinity of an active layer capable of being inhibited from cracking is obtained. This semiconductor laser device (100) includes a first semiconductor device portion (120) and a support substrate (10) bonded to the first semiconductor device portion, and the first semiconductor device portion has a cavity, a first conductivity type first cladding layer (22) having a first region (22a) having a first width in a second direction (direction A) intersecting with a first direction (direction B) in which the cavity extends and a second region (22b) having a second width smaller than the first width in the second direction, formed on the first region, and a first active layer (23) and a second conductivity type second cladding layer (24) formed on the second region of the first cladding layer.

### TECHNICAL FIELD

The present invention relates to a semiconductor laser device and a method of manufacturing the same, and more particularly, it relates to a semiconductor laser device having a semiconductor laser device portion bonded to a support substrate and a method of manufacturing the same.

### BACKGROUND ART

A nitride-based semiconductor has a large band gap or high thermal stability and is capable of controlling a band gap width by controlling compositions in crystal-growing a semiconductor layer, in general. Therefore, the nitride-based semiconductor is expected as a material allowing application to various semiconductor apparatuses including a laser light-emitting device or a high temperature device. Particularly, a laser light-emitting device employing the nitride-based semiconductor has been put into practice as a light source for a pickup corresponding to a large capacity optical disk.

In a case where the nitride-based semiconductor is employed as the laser light-emitting device, a hard growth substrate difficult to be cleaved such as a sapphire substrate is cleaved after reducing a thickness of the substrate by polishing a back surface of the growth substrate when forming cavity facets by cleavage. However, mass productivity of the laser light-emitting device was not necessarily excellent due to thermal expansion action in polishing, residual stress inside semiconductor layers after polishing or the like in addition to necessity of a step of polishing the growth substrate.

Therefore, the laser light-emitting device formed by re-bonding a nitride-based semiconductor layer formed on a side of the growth substrate to a support substrate made of a softer material than a material of the growth substrate is recently proposed, as disclosed in Japanese Patent Laying-Open No. 2007-103460, for example.

The aforementioned Japanese Patent Laying-Open No. 2007-103460 discloses a semiconductor laser device formed by separating semiconductor laser device layers formed on a sapphire substrate as a growth substrate from the sapphire substrate and re-bonding the semiconductor laser device layers to a support substrate made of Cu—W and a method of manufacturing the same. In this semiconductor laser device described in Japanese Patent Laying-Open No. 2007-103460, the semiconductor laser device layers are formed to stack an active layer, a p-type cladding layer and so on each having a smaller width than an n-type cladding layer on the n-type cladding layer having a prescribed width and to have a ridge in an upper region of the p-type cladding layer. An upper surface side of the p-type cladding layer is bonded to the support substrate through a solder layer.

When the growth substrate has a defect concentration region in a striped shape extending in a prescribed direction, states of in regions where the defect concentration region exists and the defect concentration region does not exist. In other words, the semiconductor layers are abnormally grown in the vicinity of the region where the defect concentration region exists while being normally crystal-grown on the region where the defect concentration region does not exist. Therefore, a thickness of the semiconductor layers grown in the vicinity of the defect concentration region is larger than a thickness of the semiconductor layers grown in the vicinity of the region where the defect concentration region does not exist, and hence the crystal grown semiconductor layers do not have flatness. Normally, a waveguide is formed to extend on a region having few defect concentration regions when forming the semiconductor laser device layers on a substrate having a defect concentration region. Therefore, the semiconductor layers are grown to be thicker in the region other than the waveguide since the defect concentration region of the substrate is arranged in a region other than the waveguide (side end region of the laser device in a width direction, for example). When bonding the semiconductor layers side and the support substrate to each other under a prescribed pressure in this state, regions having large thicknesses, grown in the vicinity of the defect concentration region come into contact with a surface of the substrate thereby generating warpage, internal stress and the like in the semiconductor layers. Consequently, a crack is caused on the inside of the semiconductor layers including the waveguide thereby resulting in an inferior device. Thus, in a re-bonding type semiconductor laser device, further reduction in cracks easily caused in not only the active layer but also the cladding layer on the inside of the semiconductor layers has been desired.

However, in the conventional semiconductor laser device and the method of manufacturing the same proposed in Japanese Patent Laying-Open No. 2007-103460, a width of the lower n-type cladding layer is larger (wider) than the widths of the p-type cladding layer and the active layer constituting the waveguide when forming the semiconductor laser device layers by employing the growth substrate having the defect concentration region, for example, and hence a crack starting from the semiconductor layers abnormally grown in the vicinity of the defect concentration region such as the side end regions of the laser device in the width direction is inhibited from entering the active layer and the p-type cladding layer above the active layer whereas this crack is disadvantageously likely to be caused in the n-type cladding layer in the vicinity of the active layer when re-bonding the semiconductor laser device layers to the support substrate.

### DISCLOSURE OF THE INVENTION

The present invention has been proposed in order to solve the aforementioned problems, and an object of the present invention is to provide a semiconductor laser device having a cladding layer in the vicinity of an active layer capable of being inhibited from cracking and a method of manufacturing the same.

A semiconductor laser device according to a first aspect of the present invention comprises a first semiconductor device portion and a support substrate bonded to the first semiconductor device portion, wherein the first semiconductor device portion comprises a cavity, a first conductivity type first cladding layer having a first region of a first width in a second direction intersecting with a first direction in which the cavity extends and a second region of a second width smaller than the first width in the second direction, formed on the first region, and a first active layer and a second conductivity type second cladding layer formed on the second region of the first cladding layer.

In the semiconductor laser device according to the first aspect of the present invention, as hereinabove described, the first semiconductor device portion comprises the first conductivity type first cladding layer having the first region of the first width in the second direction and the second region of the second width smaller than the first width in the second direction, formed on the first region, and the active layer and the second conductivity type second cladding layer formed on the second region of the first cladding layer, whereby a thickness of the first cladding layer formed with the second region is larger than a thickness of the first cladding layer formed without the second region by a thickness of the second region. Consequently, large power is required in order for a crack to propagate from a region of the first cladding layer formed without the second region to a region of the first cladding layer formed with the second region, and propagation of the crack is inhibited. Thus, a crack can be inhibited from propagating from the remaining region of the first cladding layer to the second region, which is a region of the first cladding layer in the vicinity of the active layer, in the semiconductor laser device having a structure obtained by bonding the support substrate to the first semiconductor device portion.

In the aforementioned semiconductor laser device according to the first aspect, the second cladding layer preferably has a planar portion and a projecting portion having a third width smaller than the second width, formed on the planar portion. According to this structure, a waveguide extending in the first direction in which the cavity extends can be easily formed by the projecting portion having the third width.

In the aforementioned structure having the projecting portion, a plurality of the projecting portions are preferably formed, and each of portions of the first active layer corresponding to the plurality of projecting portions preferably becomes a waveguide of the first semiconductor device portion. According to this structure, the first semiconductor device portion having a plurality of light-emitting points (waveguides) in the single first active layer can be easily formed in a state where the first active layer is protected from propagation of a crack.

In the aforementioned semiconductor laser device according to the first aspect, a step portion is preferably formed on the first cladding layer by the first region and the second region, and the step portion is preferably formed to extend along the first direction. According to this structure, the step portion extending in an extensional direction of a waveguide can inhibit a crack from being caused in a whole region in a cavity direction (extensional direction of the waveguide), of the second region of the first cladding layer in the vicinity of the active layer. Further, a width of the first region is large (a width of the second region is smaller than the width of the first region) especially in the vicinity of a cleavage plane, whereby the degree of warpage of the laser device in a width direction (second direction) can be reduced.

In the aforementioned structure having the step portion extending along the first direction, the second region is preferably formed on a region excluding both ends of the first region. According to this structure, it is possible that a crack is hard to propagate to the second region formed on a region excluding both side ends, also when the crack is caused in the both side ends of the first semiconductor device portion in the width direction in the manufacturing process.

In the aforementioned semiconductor laser device according to the first aspect, the second region preferably has a fourth width smaller than the second width in the vicinity of a facet of the cavity. According to this structure, a sectional area of the first semiconductor device portion in the second direction in the vicinity of the facet of the cavity is smaller than a sectional area of the first semiconductor device portion in the second direction inside the cavity, and hence bar-shaped cleavage of the first semiconductor device portion in the manufacturing process can be easily performed.

In the aforementioned semiconductor laser device according to the first aspect, widths of the first active layer and the second cladding layer in the second direction are preferably the same as the second width. According to this structure, a width of the second region of the first cladding layer can be reduced to a width equal to the width of the first active layer of the first semiconductor device portion, and hence a distance between the end of the first region and the second region can be rendered large in the second direction. Thus, the crack can be further inhibited from propagating to the second region.

In the aforementioned semiconductor laser device according to the first aspect, a plurality of the second regions of the first cladding layer are preferably formed. According to this structure, a crack is similarly inhibited from propagating to the cladding layer in the vicinity of the active layer also in a device having a plurality of laser beam emitting portions. Thus, the first semiconductor device portion having the plurality of laser beam emitting portions, in which a crack is inhibited from being caused, can be easily formed.

In the aforementioned semiconductor laser device according to the first aspect, a width of the first region is preferably smaller than a width of the support substrate. According to this structure, the semiconductor laser device can be easily separated into chips by dicing only the support substrate having a width larger than a width of the first semiconductor device portion in the second direction without interfering in the first semiconductor device portion.

In the aforementioned semiconductor laser device according to the first aspect, the semiconductor device portion preferably further includes an insulating film covering a side surface of the first region. According to this structure, the insulating film can easily inhibit adherent substances generated when forming an electrode layer on a semiconductor layer, when separating the growth substrate from the semiconductor device portion by laser beam irradiation or the like, and so on in the manufacturing process from adhering to a surface of the semiconductor device portion.

In the aforementioned semiconductor laser device according to the first aspect, a second semiconductor device portion having a second active layer is preferably formed in the support substrate. According to this structure, a multiple wavelength semiconductor laser device can be easily formed by bonding the first semiconductor device portion in which a crack is inhibited from being caused to a substrate (support substrate) formed with the second semiconductor device portion.

In the aforementioned semiconductor laser device according to the first aspect, a side of the second cladding layer of the first semiconductor device portion is preferably bonded to the support substrate. According to this structure, a re-bonding type semiconductor laser device can be formed in a state where a crack is hardly caused in the first active layer.

In the aforementioned semiconductor laser device according to the first aspect, the first semiconductor device portion and the support substrate are preferably bonded to each other through a fusion layer. According to this structure, the first semiconductor device portion can be easily bonded to the support substrate in a junction-down manner or the like.

A manufacturing process for a semiconductor laser device according to a second aspect of the present invention comprises steps of growing a first conductivity type first cladding layer, an active layer and a second conductivity type second cladding layer on a growth substrate, forming the first cladding layer to have a first region of a first width and a second region of a second width smaller than the first width, formed on the first region, and bonding a support substrate to a side of the second cladding layer on the growth substrate.

As hereinabove described, the manufacturing process for a semiconductor laser device according to the second aspect of the present invention comprises the step of forming the first cladding layer to have the first region of the first width and the second region of the second width smaller than the first width, formed on the first region, whereby a thickness of the first cladding layer formed with the second region is larger than a thickness of the first cladding layer formed without the second region by a thickness of the second region. Consequently, large power is required in order for a crack to propagate from a region of the first cladding layer formed without the second region to a region of the first cladding layer formed with the second region, and propagation of the crack is inhibited. Thus, a crack can be inhibited from propagating from the remaining region of the first cladding layer to the second region, which is a region of the first cladding layer in the vicinity of the active layer, when performing the step of bonding the support substrate to the second cladding layer of the growth substrate.

The aforementioned manufacturing process for a semiconductor laser device according to the second aspect preferably further comprises a step of removing the growth substrate. According to this structure, a semiconductor laser device having semiconductor lasers including the active layer re-bonded to the support substrate is obtained, and hence the growth substrate removed through the aforementioned step can be reemployed as a substrate for forming another semiconductor laser device.

In the aforementioned manufacturing process for a semiconductor laser device according to the second aspect, the growth substrate preferably has a defect concentration region in a striped shape. According to this structure, a waveguide can be formed in a semiconductor layer to avoid the defect concentration region in a striped shape, and hence cracks and defects in the semiconductor layer formed with the waveguide can be reduced.

In the aforementioned structure having the growth substrate having the defect concentration region, the manufacturing process preferably further comprises a step of removing the first cladding layer, the active layer and the second cladding layer in at least a part of the defect concentration region. According to this structure, a portion of a semiconductor layer abnormally grown to increase a thickness thereof in the vicinity of the defect concentration region of the growth substrate is removed, and hence the semiconductor layer formed with the waveguide can obtain constant flatness. Thus, the semiconductor layer and the support substrate can be bonded to each other without warpage, internal stress and the like resulting from a difference in a thickness of the semiconductor layer when bonding the support substrate to a side of the second cladding layer on the growth substrate. Consequently, a crack can be inhibited from being caused inside the semiconductor layer by the difference in the thickness of the semiconductor layer.

The aforementioned manufacturing process for a semiconductor laser device according to the second aspect preferably further comprises a step of forming a planar portion and a projecting portion having a third width smaller than the second width, formed on the planar portion, in the second cladding layer after the step of forming the first cladding layer to have the first region and the second region. According to this structure, a waveguide extending in a first direction in which a cavity extends can be easily formed by the projecting portion having the third width.

In the aforementioned structure comprising the step of forming the projecting portion in the second cladding layer, the step of forming the projecting portion in the second cladding layer preferably includes a step of forming a plurality of the projecting portions in the second cladding layer. According to this structure, a first semiconductor device portion having a plurality of light-emitting points (waveguides) in a single first active layer can be easily formed in a state where the first active layer is protected from propagation of a crack.

In the aforementioned manufacturing process for a semiconductor laser device according to the second aspect, the step of growing the first cladding layer preferably includes a step of growing the first cladding layer through a layer for separation on the growth substrate. According to this structure, the growth substrate can be easily separated from the first cladding layer at the layer for separation when removing the growth substrate from the semiconductor layer bonded to the support substrate.

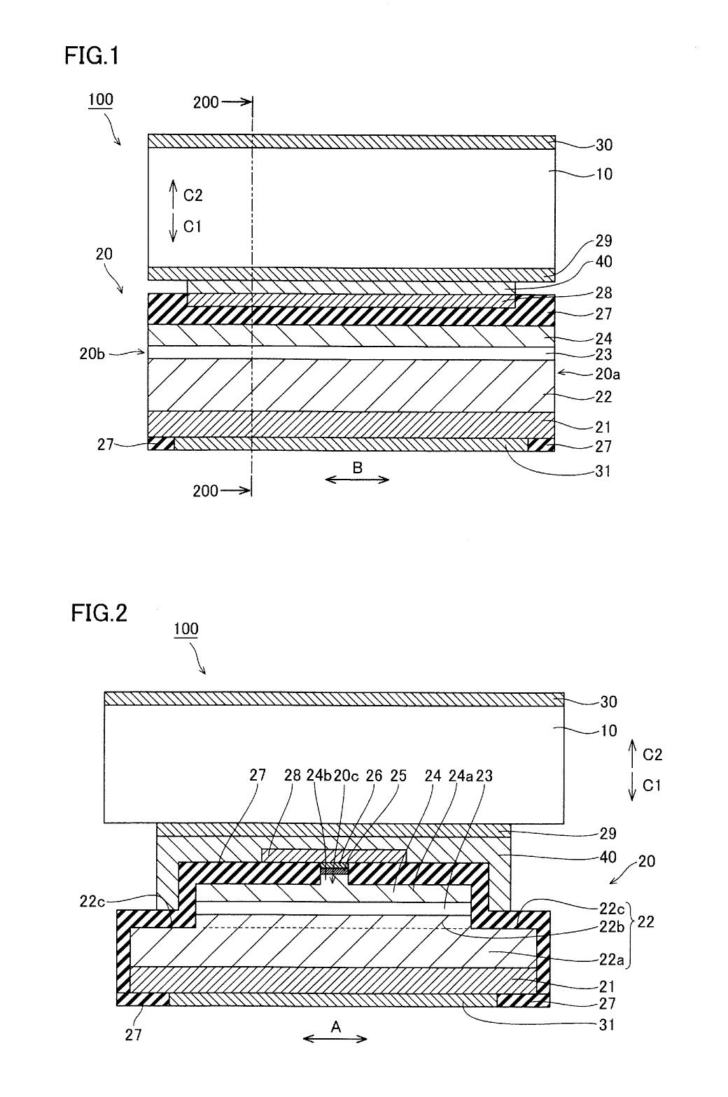

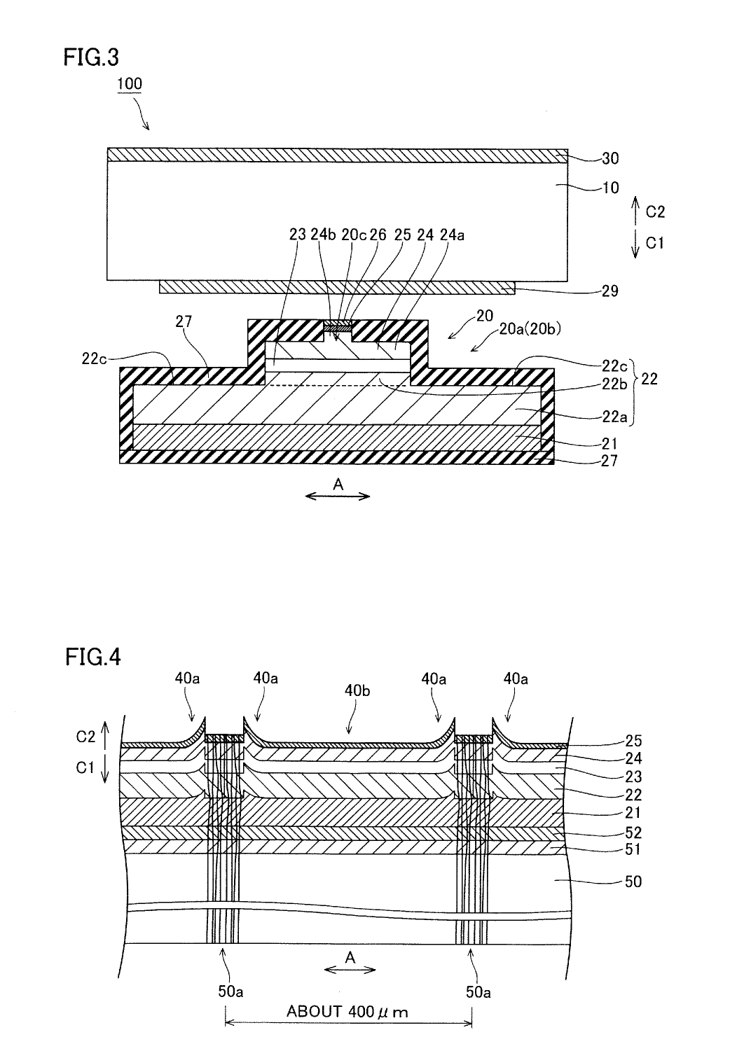

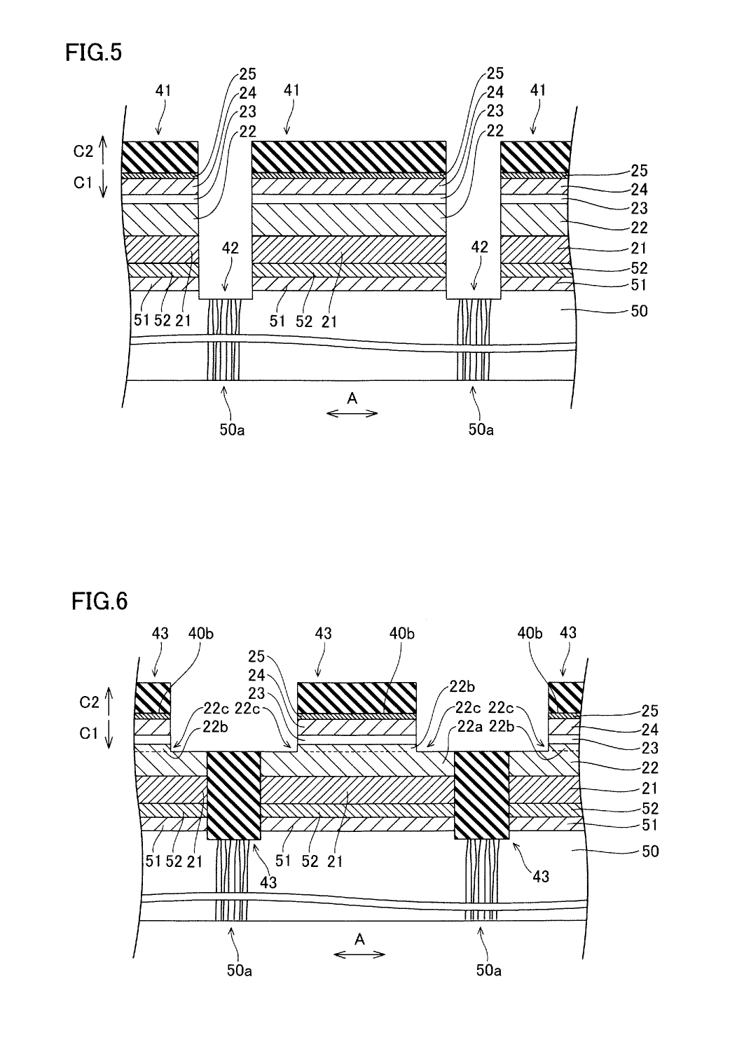

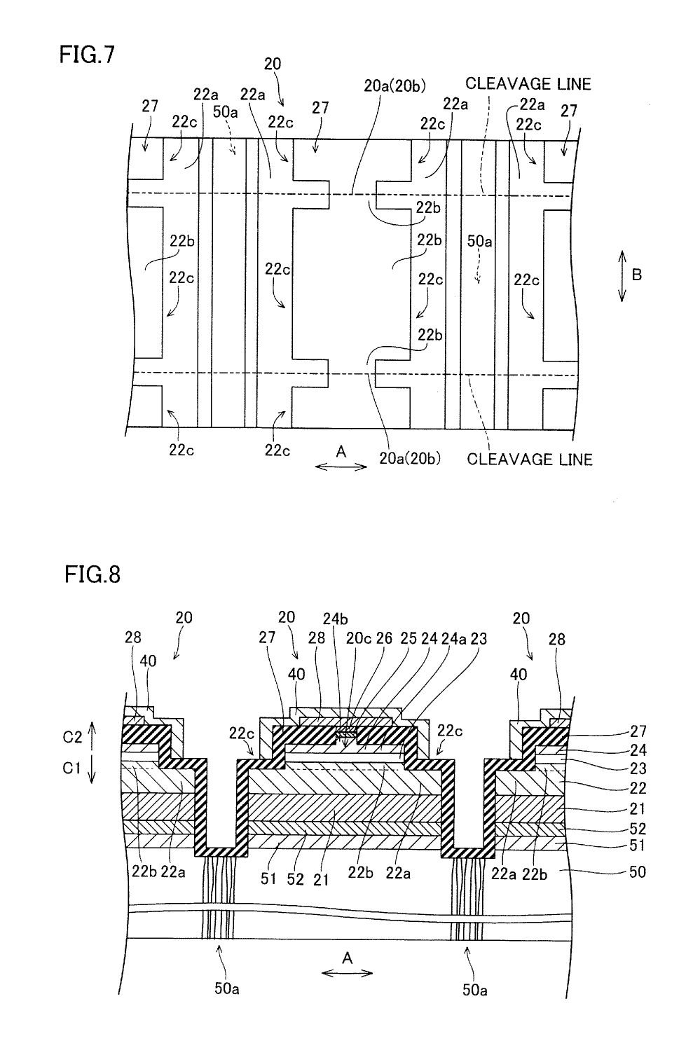

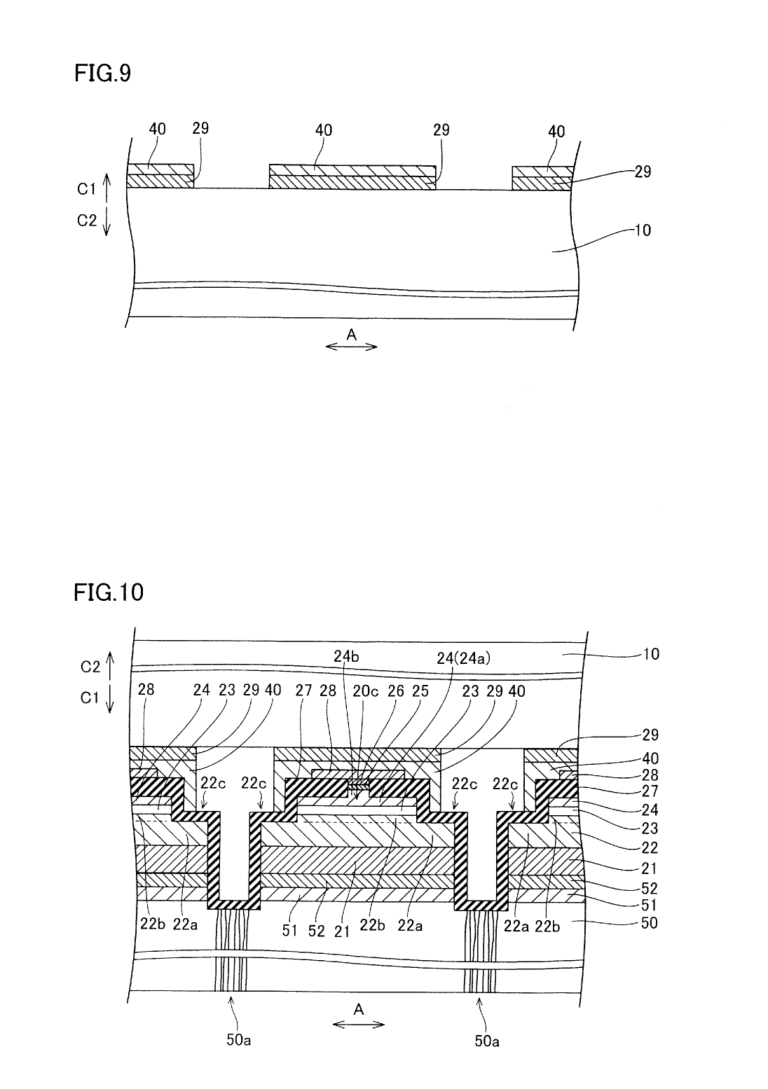

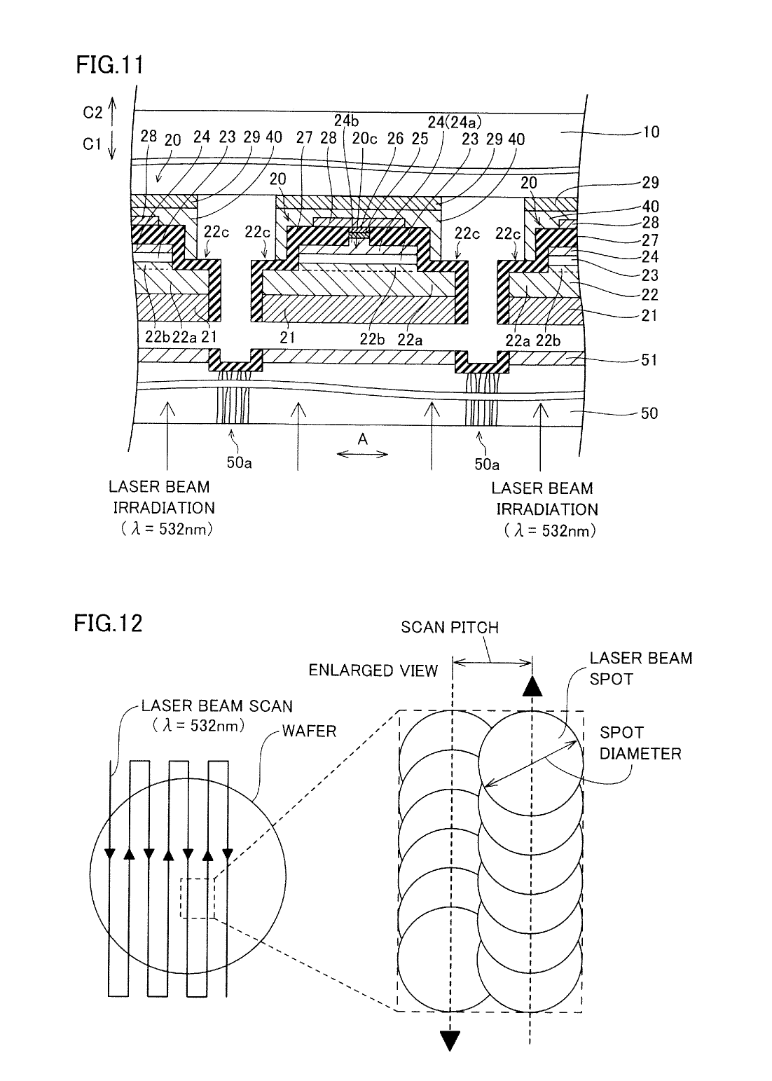

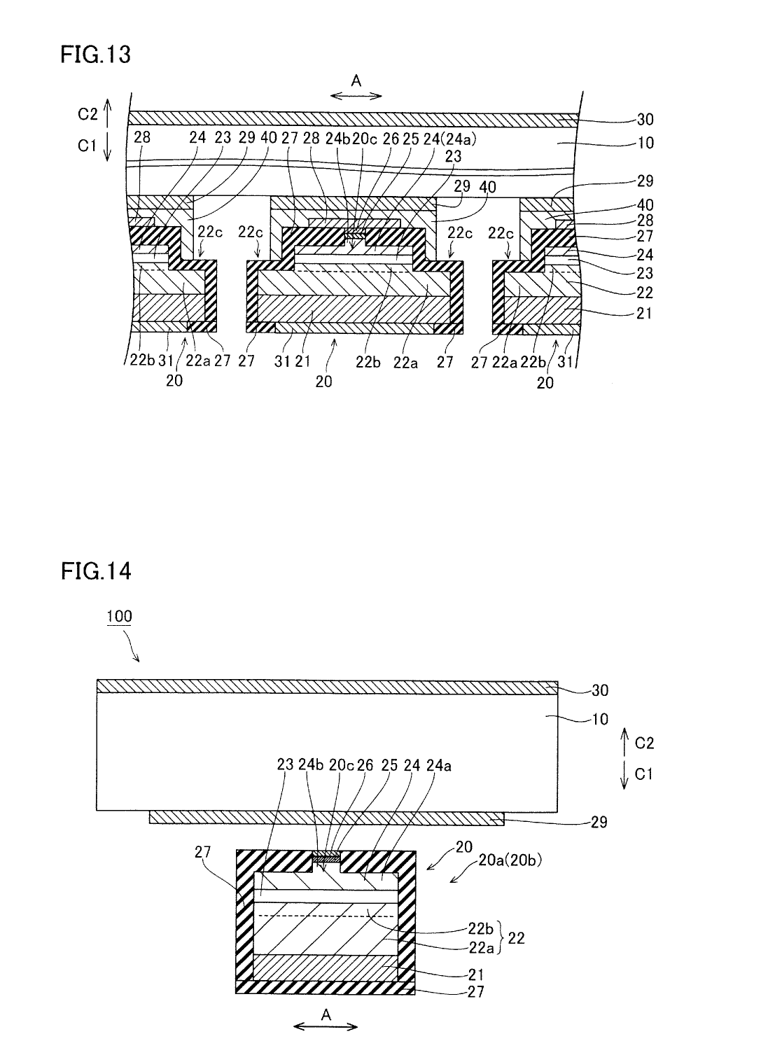

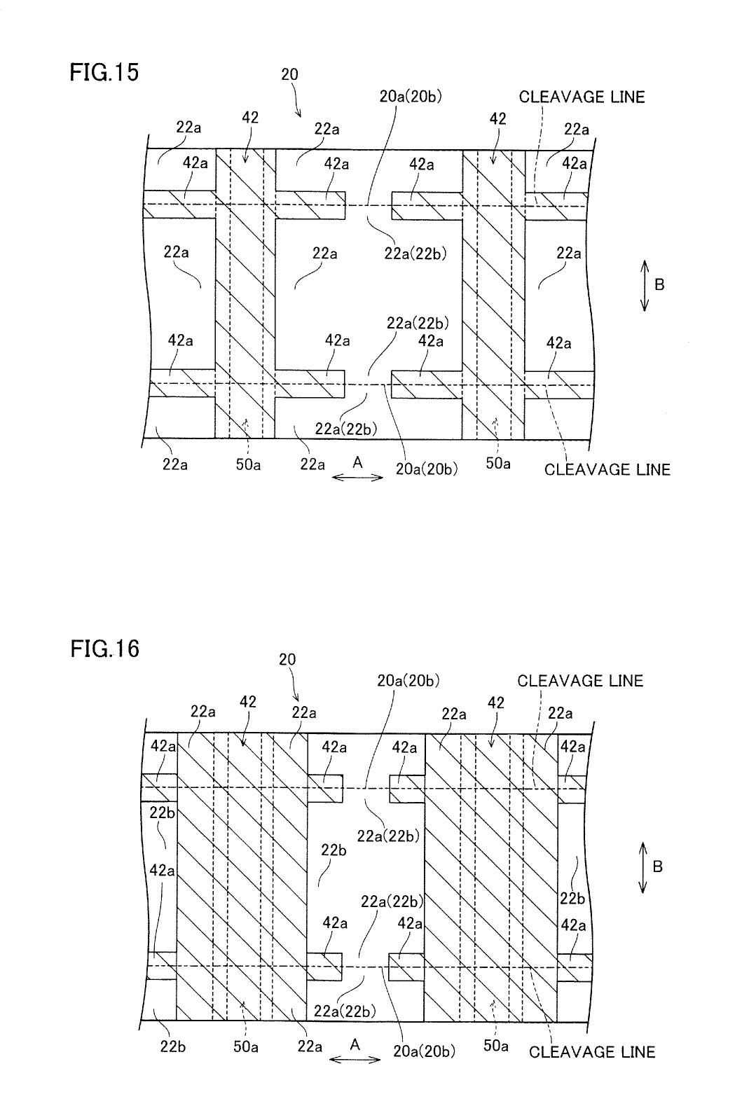

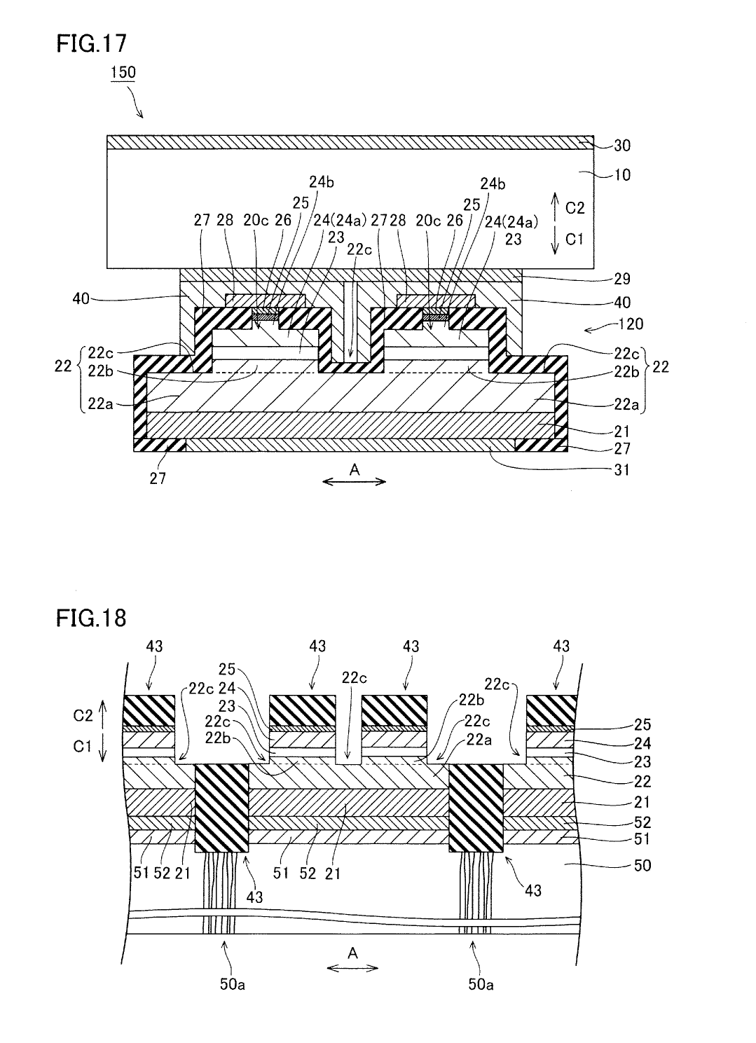

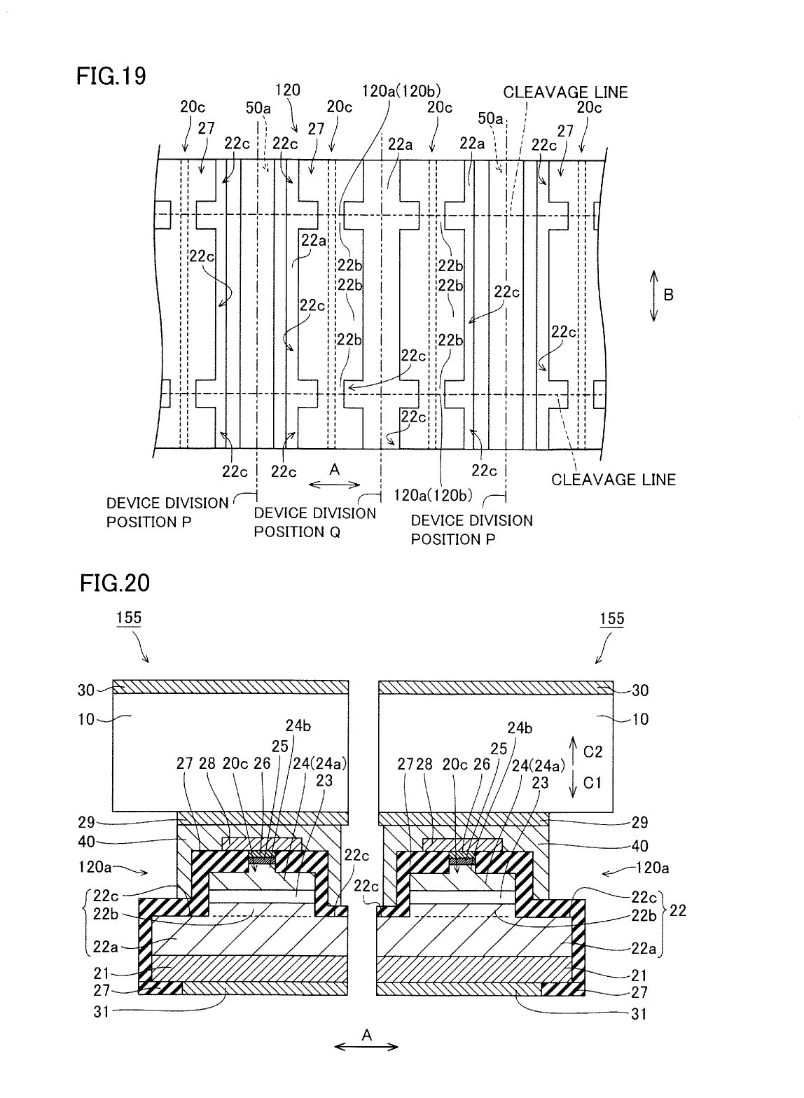

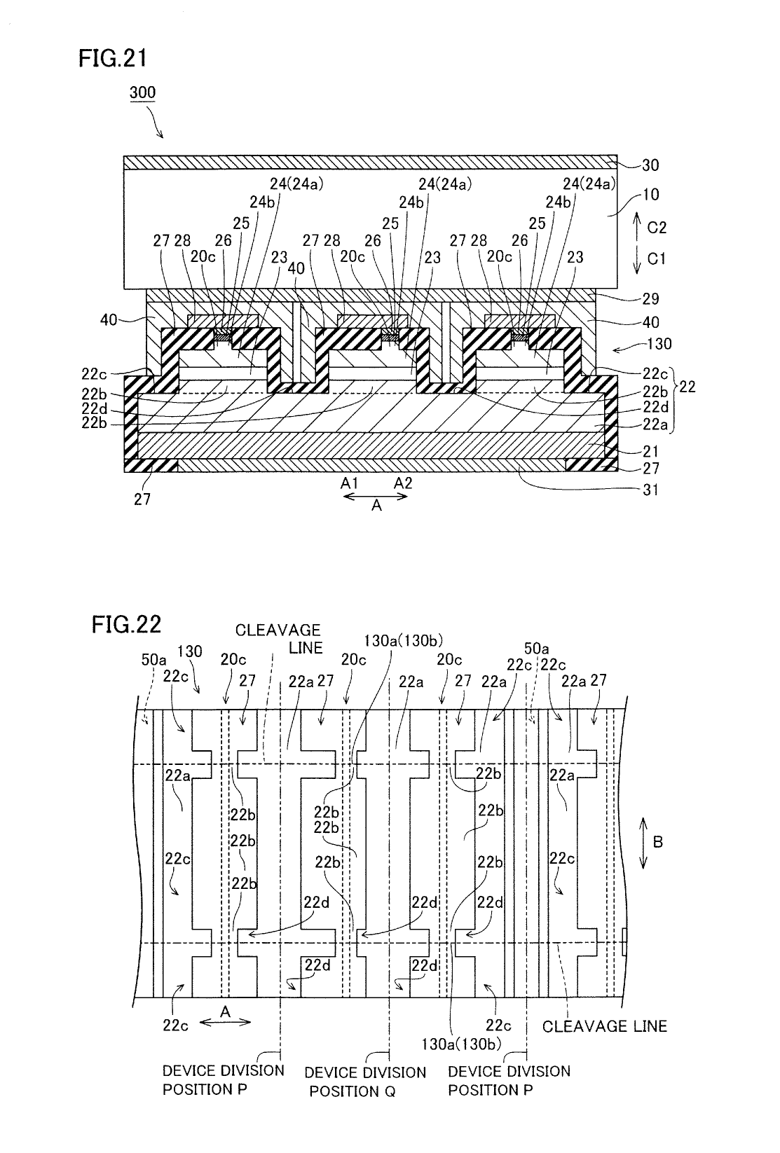

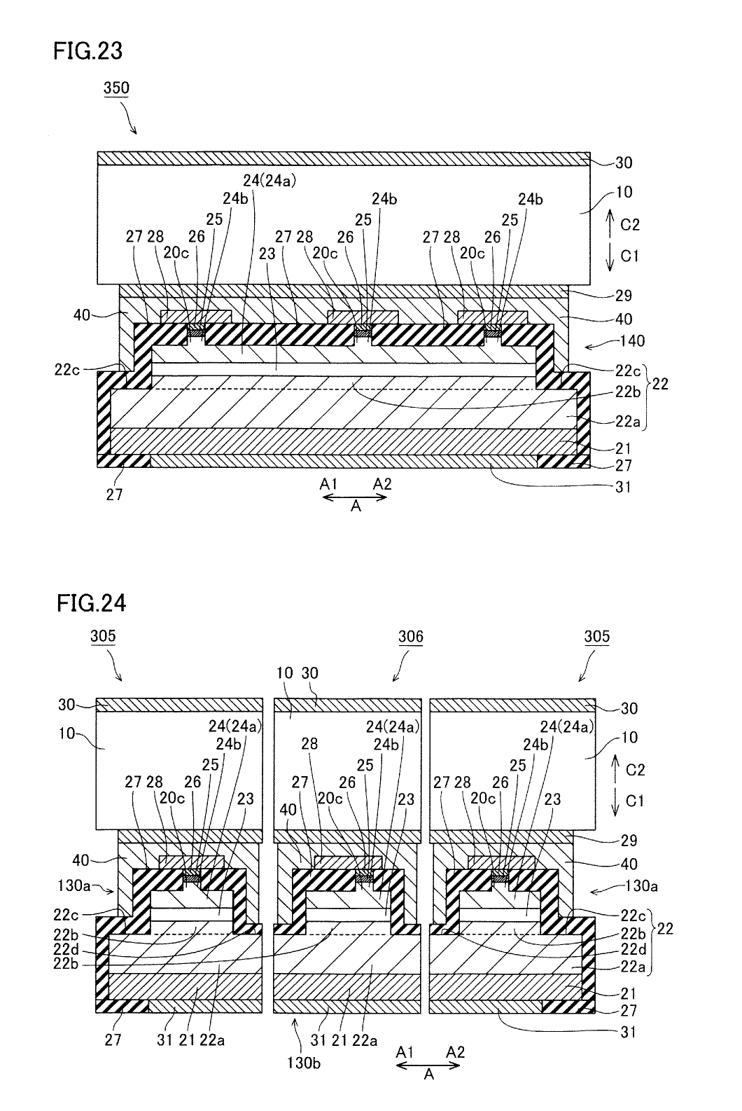

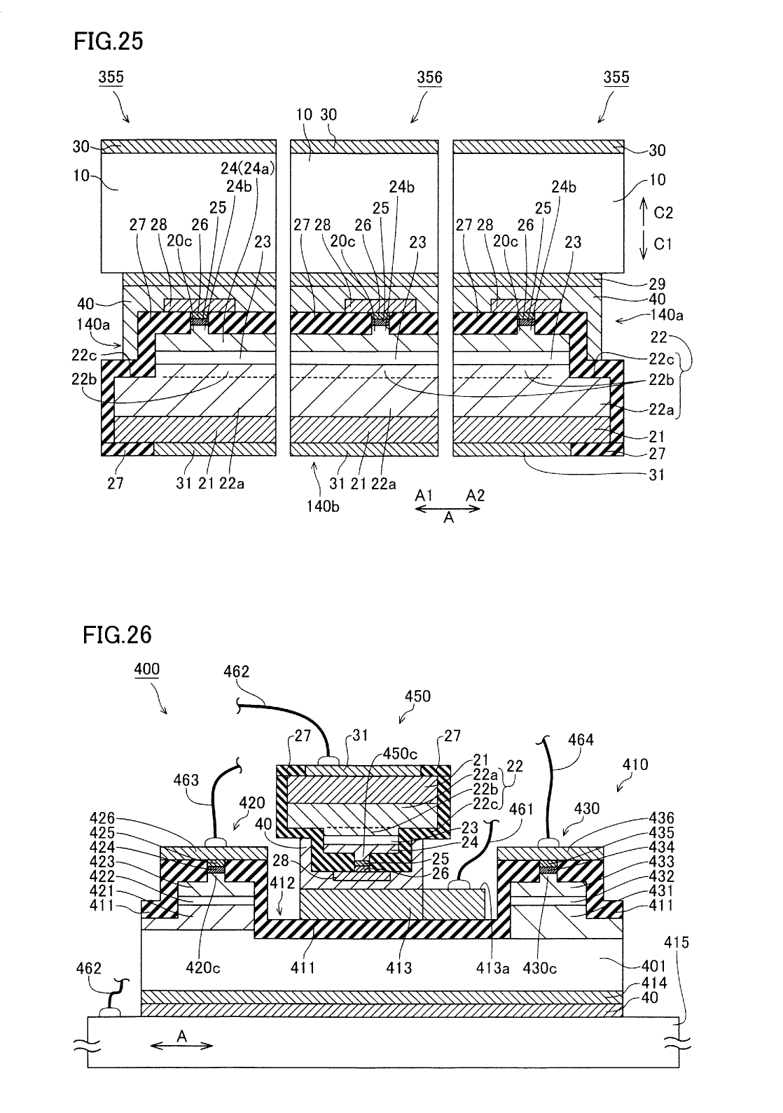

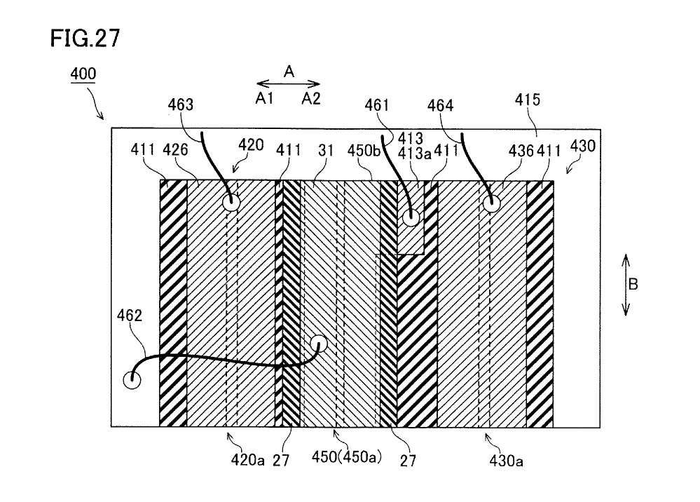

### BRIEF DESCRIPTION OF THE DRAWINGS

[FIG. 1] A sectional view of a semiconductor laser device on a surface along a cavity direction, for illustrating the structure of the semiconductor laser device according to a first embodiment of the present invention.

[FIG. 2] A sectional view taken along the line 200-200 in FIG. 1.

[FIG. 3] A sectional view of the semiconductor laser device shown in FIG. 1 on a cavity facet.

[FIG. 4] A sectional view for illustrating a manufacturing process for the semiconductor laser device according to the first embodiment shown in FIG. 1.

[FIG. 5] A sectional view for illustrating the manufacturing process for the semiconductor laser device according to the first embodiment shown in FIG. 1.

[FIG. 6] A sectional view for illustrating the manufacturing process for the semiconductor laser device according to the first embodiment shown in FIG. 1.

[FIG. 7] A plan view for illustrating the manufacturing process for the semiconductor laser device according to the first embodiment shown in FIG. 1.

[FIG. 8] A sectional view for illustrating the manufacturing process for the semiconductor laser device according to the first embodiment shown in FIG. 1.

[FIG. 9] A sectional view for illustrating the manufacturing process for the semiconductor laser device according to the first embodiment shown in FIG. 1.

[FIG. 10] A sectional view for illustrating the manufacturing process for the semiconductor laser device according to the first embodiment shown in FIG. 1.

[FIG. 11] A sectional view for illustrating the manufacturing process for the semiconductor laser device according to the first embodiment shown in FIG. 1.

[FIG. 12] A plan view for illustrating the manufacturing process for the semiconductor laser device according to the first embodiment shown in FIG. 1.

[FIG. 13] A sectional view for illustrating the manufacturing process for the semiconductor laser device according to the first embodiment shown in FIG. 1.

[FIG. 14] A sectional view on a cavity facet for illustrating the structure of a semiconductor laser device according to a modification of the first embodiment of the present invention.

[FIG. 15] A plan view for illustrating the structure of and a manufacturing process for the semiconductor laser device according to the modification of the first embodiment shown in FIG. 14.

[FIG. 16] A plan view for illustrating the structure of and the manufacturing process for the semiconductor laser device according to the modification of the first embodiment shown in FIG. 14.

[FIG. 17] A sectional view showing a structure of a semiconductor laser device according to a second embodiment of the present invention.

[FIG. 18] A sectional view for illustrating the structure of and a manufacturing process for the semiconductor laser device according to the second embodiment shown in FIG. 17.

[FIG. 19] A plan view for illustrating the structure of and the manufacturing process for the semiconductor laser device according to the second embodiment shown in FIG. 17.

[FIG. 20] A sectional view showing a structure of a semiconductor laser device according to a modification of the second embodiment of the present invention.

[FIG. 21] A sectional view showing a structure of a semiconductor laser device according to a third embodiment of the present invention.

[FIG. 22] A plan view for illustrating the structure of and a manufacturing process for the semiconductor laser device according to the third embodiment shown in FIG. 21.

[FIG. 23] A sectional view showing a structure of a semiconductor laser device according to a first modification of the third embodiment of the present invention.

[FIG. 24] A sectional view showing a structure of a semiconductor laser device according to a second modification of the third embodiment of the present invention.

[FIG. 25] A sectional view showing a structure of a semiconductor laser device according to a third modification of the third embodiment of the present invention.

[FIG. 26] A sectional view showing a structure of a semiconductor laser device according to a fourth embodiment of the present invention.

[FIG. 27] A plan view showing the structure of the semiconductor laser device according to the fourth embodiment shown in FIG. 26.

### BEST MODES FOR CARRYING OUT THE INVENTION

Embodiments of the present invention will be hereinafter described with reference to the drawings.

### First Embodiment

A structure of a semiconductor laser device 100 according to a first embodiment will be now described with reference to FIGS. 1 to 3.

In the semiconductor laser device 100 according to the first embodiment, as shown in FIG. 1, a semiconductor laser device portion 20 having a thickness of about 5 μm is bonded to a p-type Ge substrate 10 having a thickness of about 100 μm through a fusion layer 40 in a junction-down manner. The p-type Ge substrate 10 and the semiconductor laser device portion 20 are examples of the “support substrate” and the “first semiconductor device portion” in the present invention, respectively. The semiconductor laser device portion 20 is formed by a GaN-based semiconductor layer having a lasing wavelength of about 400 nm band.

The semiconductor laser device 100 has a cavity length (length in a direction B) of about 400 μm and is formed with a light-emitting surface 20a or a light-reflecting surface 20b substantially perpendicular to a maim surface of the p-type Ge substrate 10 on either side end in a cavity direction (direction B), as shown in FIG. 1. According to the present invention, the light-emitting surface 20a is distinguished by magnitude relation between the intensities of laser beams emitted from cavity facets on a light emission side and on a light reflective side. In other words, a side on which the emission intensity of the laser beam is relatively large is the light-emitting surface 20a and a side on which the emission intensity of the laser beam is relatively small is the light-reflecting surface 20b. A dielectric multilayer film (not shown) constituted by an AlN film, an Al₂O₃ film and so on is formed on each of the light-emitting surface 20a and the light-reflecting surface 20b of the semiconductor laser device 100 by facet coating treatment in the manufacturing process.

The semiconductor laser device portion 20 is formed with an n-type cladding layer 22 made of n-type AlGaN on an upper surface of an n-type contact layer 21, as shown in FIG. 2. An active layer 23 having an MQW structure made of GaInN is formed on the n-type cladding layer 22. This active layer 23 has a structure in which two barrier layers (not shown) made of undoped GaN and three well layers (not shown) made of undoped In_{0.1}Ga_{0.9}N are alternately stacked. A p-type cladding layer 24 made of p-type AlGaN and having a planar portion 24a and a projecting portion 24b with a width of about 2 μm, extending in the direction B (see FIG. 1) and protruding upward (along arrow C2) from a substantially central portion of the planar portion 24a is formed on the active layer 23. The n-type cladding layer 22 and the p-type cladding layer 24 are examples of the “first conductivity type first cladding layer” and the “second conductivity type second cladding layer” in the present invention, respectively, and the active layer 23 is an example of the “first active layer” in the present invention.

According to the first embodiment, as shown in FIG. 2, the n-type cladding layer 22 is formed to have a region 22a having a width of about 340 μm in a direction A and a region 22b formed on the region 22a, narrower than the region 22a and having a width of about 200 μm in the direction A. Thus, the n-type cladding layer 22 is formed with step portions 22c constituted by an upper surface of the region 22a and side surfaces of the region 22b. In FIG. 2, a broken line is drawn between the regions 22a and 22b in order to distinguish between the regions 22a and 22b. The region 22b is formed on a portion approaching a central portion by substantially equal distances (about 70 μm) from both side ends of the region 22a in the direction A. The active layer 23 and the p-type cladding layer 24 are so formed on the region 22b of the n-type cladding layer 22 as to have substantially the same widths (about 200 μm) as the region 22b of the n-type cladding layer 22. The region 22a and the region 22b are examples of the “first region” and the “second region” in the present invention, respectively.

As shown in FIG. 2, a p-side contact layer 25 made of undoped In_{0.05}Ga_{0.95}N and a p-side ohmic electrode 26 made of a Pd layer having a thickness of about 3 nm and an Au layer having a thickness of about 10 nm formed successively from the side closer to the p-type contact layer 25 are formed on the projecting portion of the p-type cladding layer 24. According to the first embodiment, a ridge 20c as a waveguide extending in a striped (elongated) manner in the cavity direction of the semiconductor laser device portion 20 is constituted by the projecting portion 24b of the p-type cladding layer 24, the p-side contact layer 25 and the p-side ohmic electrode 26. The ridge 20c is formed on a substantially central portion of the semiconductor laser device portion 20 located at equal distances (about 170 μm) from both side ends of the semiconductor laser device portion 20 in the direction A.

According the first embodiment, the step portions 22c of the n-type cladding layer 22 are formed to extend along an extensional direction (direction B in FIG. 1) of the ridge 20c. As shown in FIG. 2, the step portions 22c are formed to hold an upper region (active layer 23 and p-type cladding layer 24) of the region 22b of the n-type cladding layer 22 therebetween from both sides in the direction A. Thus, the region 22b (including the active layer 23 and the p-type cladding layer 24) is formed on a region excluding side ends of the region 22a in the direction A.

The semiconductor laser device portion 20 is formed by stacking a nitride-based semiconductor layer such as the n-type contact layer 21 described above after previously forming a buffer layer 51 (see FIG. 4) having a thickness of about 20 nm and an InGaN layer for separation 52 (see FIG. 4) having a thickness of about 300 nm on an upper surface of an n-type GaN substrate 50 (see FIG. 4) by metal organic chemical vapor deposition (MOCVD) in a manufacturing process described later. The n-type GaN substrate 50 and the InGaN layer for separation 52 are examples of the “growth substrate” and the “layer for separation” in the present invention, respectively.

According to the first embodiment, as shown in FIG. 2, an insulating film 27 made of SiO₂, having a thickness of about 0.5 μm is formed to cover an upper surface of the planar portion 24a excluding the projecting portion 24b of the p-type cladding layer 24 and both side surfaces of the ridge 20c (including the projecting portion 24b). The insulating film 27 is formed to cover side surfaces of the active layer 23, side surfaces including the step portions 22c, of the n-type cladding portion 22 and side surfaces of the n-type contact layer 21. As shown in FIG. 1, the insulating film 27 is formed to cover surfaces (upper surface side and lower surface side) of the n-type cladding layer 22 and the n-type contact layer 21 also in the direction B.

As shown in FIG. 2, a p-side pad electrode 28 made of a Ti layer having a thickness of about 30 nm, a Pd layer having a thickness of about 100 nm and an Au layer having a thickness of about 300 nm formed successively from the side closer to the p-side ohmic electrode 26 is formed along an upper surface of the p-side ohmic electrode 26 and an upper surface of the insulating film 27.

An ohmic electrode 29 made of an Ni layer having a thickness of about 150 nm and an Au layer having a thickness of about 300 nm formed successively from the side closer to the p-type Ge substrate 10 is formed on a lower surface of the p-type Ge substrate 10. An anode 30 made of an Ni layer having a thickness of about 100 nm and an Au layer having a thickness of about 300 nm formed successively from the side closer to the p-type Ge substrate 10 is formed on an upper surface of the p-type Ge substrate 10. The p-side pad electrode 28 and the ohmic electrode 29 are bonded to each other through the fusion layer 40.

A cathode 31 made of an Al layer having a thickness of about 6 nm, a Pd layer having a thickness of about 10 nm and an Au layer having a thickness of about 300 nm formed successively from the side closer to the n-type contact layer 21 is formed on a lower surface of the n-type contact layer 21. The insulating film 27 made of SiO₂ is formed on a region of the lower surface of the n-type contact layer 21 except a region formed with the cathode 31.

According to the first embodiment, the semiconductor laser device portion 20 has a sectional shape different from a sectional shape (see FIG. 2) on the inside in the cavity direction, on the cavity facets (the light-emitting surface 20a and the light-reflecting surface 20b) shown in FIG. 1. Specifically, the n-type cladding layer 22 is formed to have the region 22a having a width of about 340 μm in the direction A and the region 22b having a width of about 60 μm in the direction A on the light-emitting surface 20a and the light-reflecting surface 20b, as shown in FIG. 3. The active layer 23 and the p-type cladding layer 24 are so formed on the region 22b of the n-type cladding layer 22 as to have substantially the same widths (about 60 μm) as the region 22b of the n-type cladding layer 22. In other words, the semiconductor laser device portion 20 is so formed that a width of the region 22b on the cavity facets is smaller than a width of the region 22b on the inside in the cavity direction. Thus, bar-shaped cleavage of the semiconductor laser device portion 20 in the manufacturing process can be more easily performed.

According to the first embodiment, as shown in FIGS. 2 and 3, the semiconductor laser device portion 20 is so formed that a width (about 340 μm) thereof in the direction A is smaller than a width of the p-type Ge substrate 10 in the direction A.

As shown in FIGS. 1 and 3, clearances where the fusion layer 40 is not formed are provided in the vicinities of the cavity facets (the light-emitting surface 20a and the light-reflecting surface 20b). Thus, the semiconductor laser device portion 20 can be cleaved with no influence from cleavability of the support substrate in the manufacturing process.

The manufacturing process for the semiconductor laser device 100 according to the first embodiment will be now described with reference to FIGS. 1, 2 and 4 to 13.

As shown in FIG. 4, the buffer layer 51 is formed with a thickness of about 20 nm on the upper surface of the n-type GaN substrate 50 and the InGaN layer for separation 52 is formed with a thickness of about 300 nm by MOCVD. Then, the n-type contact layer 21 having a carrier concentration of about 5×10¹⁸ cm⁻³, doped with Si of about 5×10¹⁸ cm⁻³ and the n-type cladding layer 22 made of Al_{0.07}Ga_{0.93}N, having a carrier concentration of about 5×10¹⁸ cm⁻³, doped with Si of about 5×10¹⁸ cm⁻³ are successively formed on the InGaN layer for separation 52 so as to have thicknesses of about 5 μm and about 400 nm, respectively.

An n-type carrier blocking layer having a thickness of about 5 nm and made of Al_{0.16}Ga_{0.84}N, having a carrier concentration of about 5×10¹⁸ cm⁻³, doped with Si of about 5×10¹⁸ cm⁻³, an n-type optical guiding layer having a thickness of about 100 nm and made of GaN doped with Si, a multiple quantum well (MQW) active layer obtained by alternately stacking four barrier layers having thicknesses of about 20 nm and made of In_{0.02}Ga_{0.98}N and three quantum well layers having thicknesses of about 3 nm and made of In_{0.15}Ga_{0.85}N, a p-type optical guiding layer having a thickness of about 100 nm and made of GaN doped with Mg of about 4×10¹⁹ cm⁻³, and a p-type cap layer having a thickness of about 20 nm and made of Al_{0.16}Ga_{0.84}N doped with Mg of about 4×10¹⁹ cm⁻³ are successively stacked on the n-type cladding layer 22, thereby forming the active layer 23 having a thickness of about 310 nm in total.

The p-type cladding layer 24 having a thickness of about 400 nm (thickness on the ridge 20c) and made of Al_{0.07}Ga_{0.93}N, having a carrier concentration of about 5×10¹⁷ cm⁻³, doped with Mg of about 4×10¹⁹ cm⁻³ and the p-side contact layer 25 having a thickness of about 10 nm and made of In_{0.02}Ga_{0.98}N, having a carrier concentration of about 5×10¹⁷ cm⁻³, doped with Mg of about 4×10¹⁹ cm⁻³ are successively formed on the barrier layer of the active layer 23.

According to the first embodiment, the n-type GaN substrate 50 provided with a plurality of defect concentration regions 50a having a large number of crystal defects, extending along arrow B (see FIG. 1) and arranged in a striped manner at intervals of about 400 μm along arrow A (see FIG. 4) is employed as the growth substrate. The n-type GaN substrate 50 is a substrate reducing the number of crystal defects in wide regions other than the defect concentration regions 50a by forming the crystal defects in prescribed regions (defect concentration regions 50a) in a concentrated manner. Thus, semiconductor layers are formed with regions 40a crystal-grown on upper surfaces on both sides of regions provided with the defect concentration regions 50a of the n-type GaN substrate 50 to protrude upward and flat regions 40b (including regions in the vicinity of the ridge 20c (see FIG. 2)) crystal-grown on upper surfaces of the regions other than the defect concentration regions 50a, as shown in FIG. 4. The region 40a is an example of the “defect concentration region” in the present invention.

According to the first embodiment, as shown in FIG. 5, masks 41 made of SiO₂ or the like are so formed on regions corresponding to the regions 40b, of a semiconductor layer (on the p-side contact layer 25) as to have prescribed thicknesses. Then, prescribed regions are etched from the p-side contact layer 25 toward the n-type GaN substrate 50 (in a direction C1) by dry etching such as reactive ion etching with Cl₂ or the like by employing the masks 41 extending in the direction B (see FIG. 2) as masks. Thus, the regions 40a having a large number of crystal defects are removed from the semiconductor layers, and groove portions 42 extending in a striped manner in the direction B (see FIG. 1) are formed. The semiconductor layers in a region formed with the ridge 20c (see FIG. 2) can obtain constant flatness by comprising the aforementioned steps. Therefore, the semiconductor layers and the support substrate can be bonded to each other without warpage, internal stress and the like resulting from a difference in a thickness of the semiconductor layers when performing a step of bonding the support substrate described later, and hence a crack can be inhibited from being caused in the semiconductor layers due to the difference in the thickness of the semiconductor layers.

In a state shown in FIG. 5, the semiconductor layers including the n-type cladding layer 22 are formed to have widths of about 340 μm in the direction A. Thereafter, the masks 41 are removed by wet etching with hydrofluoric acid or the like.

According to the first embodiment, as shown in FIG. 6, masks 43 made of SiO₂ or the like are so formed on the regions corresponding to the regions 40b of the semiconductor layer (on the p-side contact layer 25) and the groove portions 42 as to have prescribed thicknesses. Then, prescribed regions are etched from the p-side contact layer 25 toward the n-type GaN substrate 50 by dry etching such as reactive ion etching with Cl₂ or the like by employing the masks 43 extending in the direction B (see FIG. 2) as masks. Thus, the regions 22b having widths of about 200 μm smaller than the regions 22a having widths of about 340 μm are formed in the n-type cladding layer 22. In FIG. 6, a broken line is drawn between the regions 22a and 22b in order to distinguish between the regions 22a and 22b. The active layers 23 and the p-type cladding layers 24 are so formed on the regions 22b as to have the same widths (about 200 μm) as the regions 22b.

According to the first embodiment, as shown in FIG. 7, the aforementioned etching is so performed that widths (about 60 μm) of the regions 22b of the n-type cladding layer 22 in the vicinities of the cavity facets are rendered smaller than widths (about 200 μm) of the regions 22b of the n-type cladding layer 22 on the inside in the cavity direction. Thus, widths in the direction A, of the regions 22b formed with the cavity facets (the light-emitting surface 20a and the light-reflecting surface 20b) are smaller than a width (about 340 μm) of a central portion of the semiconductor laser device portion 20 in the direction B. Thereafter, the masks 43 (see FIG. 6) are removed by wet etching with hydrofluoric acid or the like.

As shown in FIG. 8, resist patterns (not shown) are formed on an upper surface of the p-side ohmic electrode layer 26 by lithography, and prescribed regions are thereafter etched from the upper surface of the p-side contact layer 25 in the direction C1 by employing the resist patterns as masks. Thus, the ridge 20c having a width of about 2 μm, constituted by the p-side contact layer 25 and the projecting portion 24b of the p-type cladding layer 24 is formed. The ridge 20c is formed on the substantially central portion of the semiconductor laser device portion 20 located at the equal distances (about 170 μm) from the both side ends of the semiconductor laser device portion 20 in the direction A and is formed to extend in the direction B (see FIG. 7).

Then, the insulating film 27 made of SiO₂, having a thickness of about 0.5 μm is formed on an upper surface of the p-type cladding layer 24 other than the projecting portion 24b (on the planar portion 24a) and on the both side surfaces of the ridge 20c (including the projecting portion 24b), as shown in FIG. 8. At this time, according to the first embodiment, the insulating film 27 is formed to cover overall surfaces from the side surfaces of the active layer 23 and the side surfaces including the step portions 22c, of the n-type cladding portion 22 to surfaces of the groove portions 42 in the direction C1.

Thereafter, the upper surface of the p-side ohmic electrode layer 26 is exposed by removing a portion of the insulating film 27 on a region corresponding to the ridge 20c by etching, and the p-side ohmic electrode 26 (see FIG. 8) is formed on the exposed upper surface of the p-side contact layer 25 on the ridge 20c by vacuum evaporation. Then, the p-side pad electrode 28 is formed along the upper surface of the p-side ohmic electrode 26 and the upper surface of the insulating film 27. The fusion layer 40 constituted by three layers of an Au—Ge 12% alloy having a thickness of about 1 μm, an Au—Sn 90% alloy having a thickness of about 3 μm and an Au—Ge 12% alloy having a thickness of about 1 μm is previously formed on the p-side pad electrode 28 as an adhesive layer for bonding the p-type Ge substrate 10 described later. At this time, according to the first embodiment, a region where the fusion layer 40 is formed on the p-side pad electrode 28 is formed on a region inside from the vicinities of the cavity facets by prescribed distances, as shown in FIG. 1. Thus, the semiconductor laser device portion 20 is formed on the upper surface of the n-type GaN substrate 50.

Next, the ohmic electrodes 29 are formed on the upper surface of the p-type Ge substrate 10 employed as the support substrate by electron beam evaporation (EB), as shown in FIG. 9. The fusion layers 40 made of an Au—Ge 12% alloy, having thicknesses of about 1 μm are previously formed on the ohmic electrodes 29 by evaporation. At this time, according to the first embodiment, regions where the fusion layers 40 are formed on the ohmic electrodes 29 are formed to cover regions opposed to the fusion layers 40 on a side of the growth substrate (n-type GaN substrate 50) shown in FIG. 8.

As shown in FIG. 10, the side of the p-side pad electrodes 28 of the semiconductor laser device portion 20 formed on the side of the n-type GaN substrate 50 is opposed and bonded to the side of the ohmic electrodes 29 formed on a side of the p-type Ge substrate 10 through the fusion layers 40 with a load of about 100 N at a temperature of about 295° C.

Next, second harmonics of an Nd:YAG laser beam (wavelength: about 532 nm), adjusted to energy density of about 500 mJ/cm² to about 2000 mJ/cm² is applied intermittently (in pulses) to the n-type GaN substrate 50 from a lower surface side of the n-type GaN substrate 50, as shown in FIG. 11. The laser beam is applied to a whole region on the lower surface side of the n-type GaN substrate 50.

According to the first embodiment, the frequency of is adjusted to about 15 kHz, and the pulsed laser beam having a pulse width of about 10 nsec is employed. As shown in FIG. 12, the laser spot diameter is about 50 μm, and the scan pitch (shift amount with respect to each reciprocating movement) is about 40 μm. At this time, the laser beam is irradiated to an overall wafer on the lower surface side of the n-type GaN substrate 50, but the laser beam is intermittently irradiated in a spot shape, and hence shots of the laser beams are drawn while irradiated regions partly overlap with each other. Therefore, the region 22b of the semiconductor layer constituting the ridge 20c is larger than the laser spot diameter (the width of the region 22b is about 200 μm) under normal conditions for laser beam irradiation, and hence the laser beam is irradiated to the ridge 20c while the irradiated regions partly overlap with each other. In this case, the amounts of laser beam irradiation are different in portions of the irradiated regions partly overlapping with each other (overlapping with each other every about 10 μm) and the remaining portions (portions of the irradiated regions not overlapping with each other), and hence influence of transmitted laser beams on the active layer 23 is increased. Therefore, laser beam irradiation with a laser spot diameter adjusted to be larger than the width of the region 22b is further preferred, as shown in a manufacturing process of a second embodiment of the present invention described later.

The binding of crystals of the InGaN layers for separation 52 stacked therein is totally or locally destroyed by the irradiation of the laser beam. Thus, the semiconductor laser device portion 20 can be easily separated from the n-type GaN substrate 50 in a direction C2 along the breakdown region of the InGaN layers for separation 52, as shown in FIG. 11. Another laser beam source other than the YAG laser beam may be employed for the laser beam, so far as a laser beam from the laser beam source has a wavelength allowing the same to be transmitted through GaN and to be absorbed by the InGaN layer for separation 52. The n-type GaN substrate 50 separated in the direction C1 can be reemployed as the growth substrate by performing surface treatment.

Thereafter, the n-type contact layer 21 having a thickness of about 5 μm, exposed on a lower surface side of the semiconductor laser device portion 20 is formed with a thickness of about 3 μm by etching for the purpose of cleaning the surface, as shown in FIG. 13. Then, the cathode 31 is formed on the lower surface of the n-type contact layer 21. The insulating film 27 made of SiO₂, having a thickness of about 0.5 μm is formed on a region where the cathode 31 is not formed among the lower surface of the n-type contact layer 21. Thus, the wafer-state semiconductor laser device portion 20 is formed.

Thereafter, cleavage is performed in the p-type Ge substrate 10 on the wafer-state semiconductor laser device portion 20, whereby the bar-shaped semiconductor laser device 20 having the light-emitting surface 20a and the light-reflecting surface 20b (see FIG. 1) is formed. Facet coating treatment is performed on the bar-shaped semiconductor laser device 20. Thus, the dielectric multilayer film (not shown) constituted by an AlN film, an Al₂O₃ film and so on is formed on each of the light-emitting surface 20a and the light-reflecting surface 20b (see FIG. 1) of the semiconductor laser device 20.

Further, the bar-shaped semiconductor laser device 20 shown in FIG. 7 is successively divided into chips along a direction (direction B) in which a cavity extends. Thus, each chip of the semiconductor laser device 100 is formed, as shown in FIG. 2. Thus, a large number of the semiconductor laser devices 100 according to the first embodiment are manufactured.

According to the first embodiment, as hereinabove described, the semiconductor laser device 20 comprises the n-type cladding layer 22 including the region 22a having a width of about 340 μm in the direction A and the region 22b having a width of about 200 μm in the direction A, formed on the region 22a, and the active layer 23 and the p-type cladding layer 24 formed on the region 22b of the n-type cladding layer 22, whereby the n-type cladding layer 22 is formed with the region 22b having substantially the same width (about 200 μm) as the p-type cladding layer 24 constituting the ridge 20c (waveguide) extending in the cavity direction (direction B) and the active layer 23, formed on the region 22a, when forming the semiconductor laser device 20 by employing the n-type GaN substrate 50 having the defect concentration regions 50a. In this case, the thickness of the n-type cladding layer 22 in the region 22b is larger than the thickness of the n-type cladding layer 22 in the region 22a. Therefore, large power is required in order for a crack to propagate from the region 22a toward the region 22b of the n-type cladding layer 22 also when the crack is caused from the vicinity of the region 40a having a large number of crystal defects on the side ends of the semiconductor laser device portion 20 in a width direction (direction A) toward the inside of the semiconductor laser device portion 20 employing the vicinity of the region 40a as a starting point in re-bonding to the p-type Ge substrate 10, and hence the crack is inhibited from propagating to the region 22b having a width smaller than that of the region 22a of the n-type cladding layer 22. Thus, the crack can be inhibited from being caused in the n-type cladding layer 22 (region 22b) in the vicinity of the active layer 23.

According to the first embodiment, the p-type cladding layer 24 has the planar portion 24a and the projecting portion 24b having a width (about 2 μm) smaller than the width (about 200 μm) of the region 22b of the n-type cladding layer 22, formed on the substantially central portion of the planar portion 24a, whereby the waveguide extending in the cavity direction (direction B) can be easily formed by the ridge 20c formed by the projecting portion 24b.

According to the first embodiment, the step portions 22c are each formed by the region 22a and the region 22b of the n-type cladding layer 22 and are formed to extend along the extensional direction of the ridge 20c, whereby the step portions 22c extending in the extensional direction of the ridge 20c can inhibit a crack from being caused in a whole region in the cavity direction (extensional direction of the ridge 20c), of the region 22b of the n-type cladding layer 22 located in the vicinity of the active layer 23. Further, the width of the region 22a is large (the width of the region 22b is smaller than the width of the region 22a) especially in the vicinities of cleavage planes (the light-emitting surface 20a and the light-reflecting surface 20b), whereby the degree of warpage of the semiconductor laser device portion 20 in the width direction (direction A) can be reduced.

According to the first embodiment, the region 22b is formed on the region excluding the both side ends of the region 22a in the direction A, whereby it is possible that cracks are hard to propagate to the region 22b formed on the region excluding the both side ends, also when the cracks are caused in the both side ends of the semiconductor laser device portion 20 in the width direction in the manufacturing process.

According to the first embodiment, the semiconductor laser device portion 20 is so formed that the width (about 60 μm) of the region 22b of the n-type cladding layer 22 in the vicinities of the cavity facets (the light-emitting surface 20a and the light-reflecting surface 20b) is smaller than the width (about 200 μm) of the region 22b inside the cavity, whereby sectional areas of the semiconductor laser device portion 20 in the direction A in the vicinities of the cavity facets (the light-emitting surface 20a and the light-reflecting surface 20b) are smaller than a sectional area of the semiconductor laser device portion 20 in the direction A inside the cavity, and hence bar-shaped cleavage of the semiconductor laser device portion 20 can be easily performed in the manufacturing process.

According to the first embodiment, the widths of the active layer 23 and the p-type cladding layer 24 of the semiconductor laser device portion 20 in the width direction are rendered substantially the same as the width of the region 22b of the n-type cladding layer 22, whereby the width of the region 22b of the n-type cladding layer 22 can be reduced to a width equal to the width of the active layer 23, and hence a distance between the both side ends of the region 22a, where a crack is easily caused, in the direction A and the region 22b can be rendered large. Thus, a crack can be further inhibited from propagating to the region 22b, and a crack caused in the side ends of the semiconductor laser device portion 20 in the width direction can be easily inhibited from propagating to not only the region 22b but also the active layer 23 and the p-type cladding layer 24.

According to the first embodiment, the width (about 340 μm) of the region 22a of the semiconductor laser device portion 20 is rendered smaller than the width of the p-type Ge substrate 10 in the direction A, whereby the semiconductor laser device 100 can be easily separated into chips by dicing only the p-type Ge substrate 10 having a width larger than the width of the semiconductor laser device portion 20 in the direction A without interfering in the semiconductor laser device portion 20 in the manufacturing process.

According to the first embodiment, the insulating film 27 is formed to cover the surfaces of the n-type cladding layer 22, the active layer 23 and the p-type cladding layer 24, whereby the insulating film 27 can easily inhibit adherent substances generated when forming electrode layers (the p-side pad electrode 28 and the cathode 31) on the semiconductor layer, when separating the n-type GaN substrate 50 from the semiconductor laser device portion 20 by laser beam irradiation, and so on in the manufacturing process from adhering to the surface of the semiconductor laser device portion 20.

According to the first embodiment, a side in which the p-type cladding layer 24 is formed, of the semiconductor laser device portion 20 is bonded to the p-type Ge substrate 10 through the fusion layer 40 (in the junction-down manner), whereby the re-bonding type semiconductor laser device 100 can be easily formed in a state where a crack is hardly caused in the active layer 23.

### Modification of First Embodiment

According to a modification of this first embodiment, a semiconductor laser device portion 20 is so formed that a width of a light-emitting surface 20a (light-reflecting surface 20b) in a direction A is uniformized in a thickness direction (direction C1) of semiconductor layers are uniformized, dissimilarly to the aforementioned first embodiment, and this will be now described with reference to FIGS. 2 and 14.

According to the modification of the first embodiment, as shown in FIG. 14, an n-type contact layer 21 and an n-type cladding layer 22 are formed to have widths of about 60 μm in the direction A on the light-emitting surface 20a (light-reflecting surface 20b) of the semiconductor laser device portion 20. An active layer 23 and a p-type cladding layer 24 are so formed on the n-type cladding layer 22 as to have substantially the same widths (about 60 μm) as the n-type cladding layer 22. Therefore, the semiconductor laser device portion 20 is formed to have a uniform width (about 60 μm) in a direction C1 on cavity facets, as shown in FIG. 14, whereas the same is formed to have a sectional shape (a region 22a has a width of about 340 μm and a region 22b has a width of about 200 μm) shown in FIG. 2 on the inside in a cavity direction.

The remaining structure of a semiconductor laser device 100 according to the modification of the first embodiment is similar to that of the aforementioned first embodiment.

A manufacturing process for the semiconductor laser device 100 according to the modification of the first embodiment will be now described with reference to FIGS. 4 to 6, 8 and 14 to 16.

The semiconductor layers are grown on an upper surface of an n-type GaN substrate 50 through the manufacturing process similar to that of the first embodiment, as shown in FIG. 4. Then, prescribed regions are etched from a p-side contact layer 25 toward the n-type GaN substrate 50 (in the direction C1) by employing masks 41 formed on the p-side contact layer 25 as masks, as shown in FIG. 5.

In the manufacturing process according to the modification of the first embodiment, groove portions 42 (hatched regions) after etching extend in a striped manner in a direction B by varying mask patterns of the masks 41 (see FIG. 5), and etching is also performed to form groove portions 42a extending by a prescribed distance (about 170 μm) in the direction A in the vicinities of regions formed with the cavity facets, as shown in FIG. 15. Thus, all the semiconductor layers from the n-type GaN substrate 50 (see FIG. 5) to the p-side contact layer 25 (see FIG. 5) are formed to have widths of about 60 μm in the direction A by the groove portions 42a in the vicinity of the region 22a formed with the cavity facets.

Thereafter, the masks 41 are partly removed by etching, thereby forming narrow masks 43 as shown in FIG. 6 on the p-side contact layer 25. Following this, prescribed regions are etched from the p-side contact layer 25 toward the n-type GaN substrate 50 by employing the masks 43 as masks. At this time, in the manufacturing process according to the modification of the first embodiment, only the semiconductor layers in portions (hatched regions) except regions formed with the cavity facets are etched, as shown in FIG. 16. Thus, regions 22b having widths of about 200 μm as shown in FIG. 6 are formed on the inside in the cavity direction. The active layers 23 and the p-type cladding layers 24 are formed to have the same widths (about 200 μm) as the regions 22b on the regions 22b. Then, the masks 43 (see FIG. 6) are removed by wet etching with hydrofluoric acid or the like.

Thereafter, a ridge 20c (see FIG. 8), an insulating film 27 (see FIG. 8) and so on are successively formed thereby forming the semiconductor laser device portion 20 through the manufacturing process similar to the first embodiment. The remaining manufacturing process in the modification of the first embodiment is similar to the manufacturing process of the aforementioned first embodiment. Thus, the semiconductor laser device 100 according to the modification of the first embodiment shown in FIG. 14 is manufactured.

According to the modification of the first embodiment, as hereinabove described, a width (about 60 μm, a width uniformized in the direction C1) of the semiconductor laser device portion 20 in the direction A on the light-emitting surface 20a (light-reflecting surface 20b) is rendered smaller than a width (the region 22a has a width of about 340 μm and the region 22b has a width of about 200 μm) thereof in the direction A on the inside in the cavity direction, whereby cleavage of the semiconductor laser device portion 20 can be more easily performed in the manufacturing process. The remaining effects of the modification of the first embodiment are similar to those of the aforementioned first embodiment.

### Second Embodiment

According to a second embodiment, a single semiconductor laser device portion 120 having a cavity length of about 800 μm is formed to have two ridges 20c substantially parallel to each other, dissimilarly to the aforementioned first embodiment, and this will be now described with reference to FIGS. 17 to 19. The semiconductor laser device portion 120 is an example of the “first semiconductor device portion” in the present invention.

According to the second embodiment, as shown in FIG. 17, an n-type cladding layer 22 is formed to have a region 22a having a width of about 340 pm in a direction A and two regions 22b formed on the region 22a, narrower than the region 22a and having widths of about 80 μm in the direction A. Thus, the n-type cladding layer 22 is formed with three step portions 22c constituted by an upper surface of the region 22a and side surfaces of the two regions 22b. In FIG. 17, a broken line is drawn between the region 22a and the regions 22b in order to distinguish between the region 22a and the two regions 22b. An active layers 23 and a p-type cladding layers 24 are so formed on each of the two regions 22b of the n-type cladding layer 22 as to have substantially the same widths (about 80 μm) as the regions 22b of the n-type cladding layer 22.

According to the second embodiment, the semiconductor laser device portion 120 is formed with the two ridges 20c extending in a striped manner in a cavity direction (direction B in FIG. 19) of the semiconductor laser device portion 120, constituted by two projecting portions 24b of the p-type cladding layer 24, p-side contact layers 25 and p-side ohmic electrodes 26.

According to the second embodiment, as shown in FIG. 19, the n-type cladding layer 22 is formed to have the region 22a (see FIG. 18) having a width of about 340 μm in the direction A and the regions 22b having widths of about 40 μm in the direction A in the vicinities of a light-emitting surface 120a and a light-reflecting surface 120b after bar-shaped cleavage. The active layer 23 and the p-type cladding layer 24 are so formed on each of the regions 22b of the n-type cladding layer 22 as to have substantially the same widths (about 40 μm) as the regions 22b of the n-type cladding layer 22. In other words, the semiconductor laser device portion 120 is so formed that widths of the regions 22b on cavity facets are smaller than widths (about 80 μm) of the regions 22b on the inside in the cavity direction. Thus, cleavage of the semiconductor laser device portion 120 in the manufacturing process can be more easily performed. The remaining structure of a semiconductor laser device 150 according to the second embodiment is similar to that of the aforementioned first embodiment.

A manufacturing process for the semiconductor laser device 150 according to the second embodiment will be now described with reference to FIGS. 4 and 17 to 19.

In the manufacturing process according to the second embodiment, the two regions 22b having widths of about 80 μm smaller than the region 22a having a width of about 340 μm are formed in the n-type cladding layer 22 by dry etching such as reactive ion etching with Cl₂ or the like after a step of removing regions 40a (see FIG. 4) having a large number of crystal defects from a semiconductor layer, as shown in FIGS. 18 and 19. Further, the active layer 23 and the p-type cladding layer 24 are so formed on each of the two regions 22b as to have the same widths (about 80 μm) as the regions 22b, as shown in FIG. 18. Thus, cracks are inhibited from being caused in the ridges 20c formed on the respective two regions 22b of the n-type cladding layer 22, similarly to the manufacturing process of the aforementioned first embodiment. Thereafter, semiconductor laser device portion 120 is divided into chips at device division positions P shown in FIG. 19 after bar-shaped cleavage.

In the manufacturing process according to the second embodiment, the laser spot diameter is adjusted to about 90 μm and the scan pitch is set to about 80 μm when performing a step of separating a growth substrate (n-type GaN substrate 50) from the semiconductor laser device portion 120. According to this structure, the laser spot diameter is larger than the width (about 80 μm) of the single region 22b, and hence a state where laser beams transmitted through the regions 22b are irradiated to each of the regions 22b while overlapping with each other is avoided when the irradiated laser beams pass through the two regions 22b. Thus, influence of the transmitted laser beams on the regions 22b and the active layer can be reduced.

The remaining manufacturing process in the second embodiment is similar to the manufacturing process of the aforementioned first embodiment. Thus, the semiconductor laser device 150 according to the second embodiment shown in FIG. 17 is manufactured.

According to the second embodiment, as hereinabove described, the two regions 22b are formed in the n-type cladding layer 22, whereby cracks caused in side ends of the semiconductor laser device portion 120 in the direction A are inhibited from propagating to both of the two regions 22b. Thus, the semiconductor laser device portion 120 having a plurality of laser beam emitting portions, in which a crack is inhibited from being caused, can be easily formed. The remaining effects of the second embodiment are similar to those of the aforementioned first embodiment.

### Modification of Second Embodiment

According to a modification of this second embodiment, semiconductor laser devices 155 each brought into a chip state and having only one ridge 20c (waveguide) is formed, dissimilarly to the aforementioned second embodiment, and this will be now described with reference to FIGS. 17, 19 and 20.

According to the modification of the second embodiment, in the semiconductor laser device 155, a semiconductor laser device portion 120a having the single ridge 20c is bonded onto a lower surface of a p-type Ge substrate 10, as shown in FIG. 20. In other words, in addition to division of the p-type Ge substrate 10 at device division positions P corresponding to both side ends of a semiconductor laser device portion 120, the p-type Ge substrate 10 and the semiconductor laser device portion 120 are divided at a device division position Q corresponding to a step portion 22c in a substantially central portion of the semiconductor laser device portion 120 in a direction A when performing a dividing step in the manufacturing process in the aforementioned second embodiment, as shown in FIG. 19. Thus, the semiconductor laser device 150 shown in FIG. 17 is further divided into two parts thereby forming the semiconductor laser devices 155.

### Third Embodiment

According to a third embodiment, a single semiconductor laser device portion 130 has substantially parallel three ridges 20c to each other, dissimilarly to the aforementioned second embodiment, and this will be now described with reference to FIGS. 18, 21 and 22. The semiconductor laser device portion 130 is an example of the “first semiconductor device portion” in the present invention.

According to the third embodiment, an n-type cladding layer 22 has a region 22a having a width of about 360 μm in a direction A and three regions 22b each having a width of about 60 μm in the direction A, as shown in FIG. 21. Thus, two recess portions 22d and step portions 22c are formed between the adjacent regions 22b and on both ends in the direction A respectively by an upper surface of the region 22a and side surfaces of the three regions 22b. An active layer 23 and a p-type cladding layer 24 are so formed on each of the three regions 22b as to have substantially the same widths (about 60 μm) as the regions 22b of the n-type cladding layer 22.

According to the third embodiment, the semiconductor laser device portion 130 is formed with the three ridges 20c extending in a striped manner in a direction B, constituted by three projecting portions 24b of the p-type cladding layer 24, a p-side contact layer 25 and a p-side ohmic electrode 26. The ridges 20c aligning with each other in the direction A are formed at intervals of about 126 μm and about 84 μm successively from an A1 side to an A2 side. In other words, the two ridges 20c on both sides are formed on a substantially central portion of the p-type cladding layer 24, whereas the central one is formed on a position deviating to the A2 side from the center of the p-type cladding layer 24. A high resistance region (region of semiconductor layers including a small amount of impurities as compared with portions therearound) having a width of about several 10 μm is formed in a central portion between defect concentration regions 50a in the semiconductor layers when crystal-growing the semiconductor layers by employing a growth substrate (n-type GaN substrate 50) provided with the defect concentration regions 50a (see FIG. 18) in the manufacturing process, similarly to the aforementioned second embodiment. Therefore, the ridges 20c must be formed to avoid the high resistance region in these semiconductor layers, and the central ridge 20c is formed on the position deviating to the A2 side from the center of the p-type cladding layer 24.

According to the third embodiment, the n-type cladding layer 22 is formed to have the region 22a having a width of about 360 μm in the direction A and the regions 22b having widths of about 30 μm in the direction A in the vicinities of a light-emitting surface 130a and a light-reflecting surface 130b formed by bar-shaped cleavage, as shown in FIG. 22. Further, the active layer 23 and the p-type cladding layer 24 are formed to have substantially the same widths (about 30 μm) as the regions 22b of the n-type cladding layer 22 in the vicinities of the light-emitting surface 130a and the light-reflecting surface 130b. The remaining structure of a semiconductor laser device 300 according to the third embodiment is similar to that of the aforementioned second embodiment. A manufacturing process for the semiconductor laser device 300 according to the third embodiment is similar to that of the aforementioned second embodiment except a step of forming the three regions 22b on the n-type cladding layer 22 by etching and dividing a p-type Ge substrate 10 at device division positions P shown in FIG. 22.

According to the third embodiment, as hereinabove described, the three regions 22b are formed in the n-type cladding layer 22, whereby cracks caused on side ends of the semiconductor laser device portion 130 in the direction A are inhibited from propagating to the three regions 22b through the region 22a. Thus, the semiconductor laser device portion 130 having a plurality of laser beam emitting portions, in which a crack is inhibited from being caused, can be easily formed. The remaining effects of the third embodiment are similar to those of the aforementioned second embodiment.

### First Modification of Third Embodiment

According to a first modification of this third embodiment, a single region 22b is formed with three ridges 20c parallel to each other, dissimilarly to the aforementioned third embodiment, and this will be now described with reference to FIG. 23.

According to the first modification of the third embodiment, an n-type cladding layer 22 of a semiconductor laser device portion 140 has a region 22a having a width of about 360 μm in a direction A and the single region 22b having a width of about 290 μm in the direction A, as shown in FIG. 23. The semiconductor laser device portion 140 is an example of the “first semiconductor device portion” in the present invention. Three ridges 20c are formed at intervals of about 126 μm and about 86 μm in the direction A in the region 22b, similarly to the aforementioned third embodiment. In other words, according to the first modification of the third embodiment, step portions 22c are formed on both sides of the region 22b in the direction A, whereas the recess portions 22d according to the aforementioned third embodiment are not formed between the ridges 20c. The remaining structure of a semiconductor laser device 350 according to the first modification of the third embodiment is similar to that of the aforementioned third embodiment. A manufacturing process for the semiconductor laser device 310 according to the first modification of the third embodiment is similar to that of the aforementioned first embodiment except a step of forming the three ridges 20c in the n-type cladding layer 22 by etching.

According to the first modification of the third embodiment, as hereinabove described, the three ridges 20c are formed in the single region 22b, whereby the semiconductor laser device portion 140 having a plurality of light-emitting points (waveguides) in a single active layer 23 can be easily formed in a state where the active layer 23 is protected from propagation of a crack.

### Second Modification of Third Embodiment

According to a second modification of this third embodiment, semiconductor laser devices 305 and 306 each brought into a chip state and having only one ridge 20c (waveguide) are formed, dissimilarly to the aforementioned third embodiment, and this will be now described with reference to FIGS. 21, 22 and 24.

According to the second modification of the third embodiment, in each of the semiconductor laser devices 305 and 306, a semiconductor laser device portion 130a (130b) having the single ridge 20c is bonded onto a lower surface of a p-type Ge substrate 10, as shown in FIG. 24. In other words, in addition to division of the p-type Ge substrate 10 at device division positions P, the p-type Ge substrate 10 and a semiconductor laser device portion 130 are divided at device division positions Q when performing a step of dividing a device in the manufacturing process in the aforementioned third embodiment, as shown in FIG. 22. Thus, the semiconductor laser device 300 shown in FIG. 21 is further divided into three parts thereby forming the semiconductor laser devices 305 and 306 (see FIG. 24).

### Third Modification of Third Embodiment

According to a third modification of this third embodiment, semiconductor laser devices 355 and 356 each brought into a chip state and having only one ridge 20c (waveguide) are formed, similarly to the second modification of the aforementioned third embodiment, and this will be now described with reference to FIGS. 23 and 25.

According to the third modification of the third embodiment, in each of the semiconductor laser devices 355 and 356, a semiconductor laser device portion 140a (140b) having the single ridge 20c is bonded onto a lower surface of a p-type Ge substrate 10, as shown in FIG. 25. In other words, in addition to division of the p-type Ge substrate 10 at positions of the p-type Ge substrate 10 corresponding to both side ends of a semiconductor laser device portion 140 (see FIG. 23) in a direction A, the p-type Ge substrate 10 and the semiconductor laser device portion 140 are divided at positions corresponding to regions (two regions) held between the ridges 20c adjacent to each other inside the semiconductor laser device portion 140 in the direction A when performing a step of dividing a device in the manufacturing process in the first modification of the aforementioned third embodiment. Thus, the semiconductor laser device 350 shown in FIG. 23 is further divided into three parts thereby forming the semiconductor laser devices 355 and 356 (see FIG. 25).

### Fourth Embodiment

According to a fourth embodiment, a blue semiconductor laser device formed through the manufacturing process similar to that of the aforementioned first embodiment is bonded to a support substrate formed with a two-wavelength semiconductor laser device thereby forming a three-wavelength semiconductor laser device, and this will be now described with reference to FIGS. 26 and 27.

In a three-wavelength semiconductor laser device 400 according to the fourth embodiment, a blue semiconductor laser device portion 450 is bonded onto a surface of a two-wavelength semiconductor laser device 410 having a red semiconductor laser device portion 420 and an infrared semiconductor laser device portion 430 integrally formed on an n-type GaAs substrate 401 in a junction-down manner, as shown in FIG. 26. The blue semiconductor laser device portion 450 is an example of the “first semiconductor device portion” in the present invention, and the red semiconductor laser device portion 420 and the infrared semiconductor laser device portion 430 are examples of the “second semiconductor device portion” in the present invention. The n-type GaAs substrate 401 is an example of the “substrate” in the present invention.

The red semiconductor laser device portion 420 of the two-wavelength semiconductor laser device 410 has an n-type cladding 421 made of AlGaInP, an active layer 422 having an MQW structure obtained by stacking barrier layers made of AlGaInP and a p-type cladding layer 423 made of AlGaInP on an upper surface of the n-type GaAs substrate 401.

The infrared semiconductor laser device portion 430 has an n-type cladding 431 made of AlGaAs, an active layer 432 having an MQW structure in which quantum well layers made of AlGaAs having a lower Al composition and barrier layers made of AlGaAs having a higher Al composition are alternately stacked and p-type cladding layer 433 made of AlGaAs. The active layers 422 and 432 are examples of the “second active layer” in the present invention.

A p-side contact layer 424 and a p-side ohmic electrode 425 are formed on a projecting portion of the p-type cladding layer 423 thereby forming a ridge 420c, and a p-side contact layer 434 and a p-side ohmic electrode 435 are formed on a projecting portion of the p-type cladding layer 433 thereby forming a ridge 430c. Further, an insulating film 411 made of SiO₂ is formed to cover side surfaces of the ridge 420c (430c) and surfaces of semiconductor layers.

A recess portion 412 concaved toward the n-type GaAs substrate 401 and having a bottom portion of a flat surface is formed in a region where the red semiconductor laser device portion 420 and the infrared semiconductor laser device portion 430 are opposed to each other in a direction A. As shown in FIGS. 26 and 27, a pad electrode 413 extending along a direction B (see FIG. 27) is formed on a prescribed region on the recess portion 412.

P-side pad electrodes 426 and 436 are formed along upper surfaces of the p-side ohmic electrodes 425 and 435, respectively and an upper surface of the insulating film 411. A cathode 414 is formed on a lower surface of the n-type GaAs substrate 401.

According to the fourth embodiment, the blue semiconductor laser device portion 450 having a device structure similar to the semiconductor laser device portion 20 described in the aforementioned first embodiment and formed with a single ridge 450c is bonded to the pad electrode 413 on the recess portion 412 through a fusion layer 40.

The blue semiconductor laser device portion 450 and the two-wavelength semiconductor laser device 410 are so bonded to each other that a light-emitting surface 450a of the blue semiconductor laser device portion 450 and a light-emitting surface 420a (430a) of the two-wavelength semiconductor laser device 410 are aligned on the same plane, as shown in FIG. 27, when the three-wavelength semiconductor laser device 400 is viewed in a planar manner.

The blue semiconductor laser device portion 450 is connected to a lead terminal through a metal wire 461 wire-bonded to a wire-bonding region 413a protruding from the pad electrode 413 in a direction A2 on a side of a light-reflecting surface 450b and is connected to a protruding block 415 through a metal wire 462 wire-bonded to an upper surface of a cathode 31. The red semiconductor laser device portion 420 is connected to a lead terminal through a metal wire 463 wire-bonded to an upper surface of the p-side pad electrode 426, and the cathode 414 is electrically connected to the protruding block 415 through the fusion layer 40. The infrared semiconductor laser device portion 430 is connected to a lead terminal through a metal wire 464 wire-bonded to an upper surface of the p-side pad electrode 436. Thus, the three-wavelength semiconductor laser device 400 is connected to the lead terminals in which the p-side pad electrodes of all the semiconductor laser devices are insulated to each other, and the cathodes are connected to a common cathode terminal.

According to the fourth embodiment, as hereinabove described, the blue semiconductor laser device portion 450 is bonded to the two-wavelength semiconductor laser device 410 having the red semiconductor laser device portion 420 and the infrared semiconductor laser device portion 430 integrally formed on the n-type GaAs substrate 401, whereby the three-wavelength semiconductor laser device can be easily formed by bonding the blue semiconductor laser device portion 450 (first semiconductor device portion) in which a crack is inhibited from being caused to the two-wavelength semiconductor laser device 410 (support substrate).

Although the present invention has been described and illustrated in detail, it is clearly understood that the same is by way of illustration and example only and is not to be taken by way of limitation, the spirit and scope of the present invention being limited only by the terms of the appended claims.

For example, while the “first semiconductor device portion” in the present invention is constituted by a nitride-based semiconductor layer in each of the aforementioned first to fourth embodiments, the present invention is not restricted to this but the first semiconductor device portion may be constituted by another semiconductor layer other than a nitride-based semiconductor layer.

While the fusion layer 40 is formed on each of the p-side pad electrode 28 on the side of the growth substrate and the ohmic electrode 29 on the side of the support substrate, and thereafter the p-side pad electrode 28 and the ohmic electrode 29 are bonded to each other when bonding the substrates to each other in each of the aforementioned first to third embodiments, the present invention is not restricted to this but the fusion layer 40 may be formed only on either the p-side pad electrode 28 on the growth substrate or the ohmic electrode 29 on the support substrate.

While the p-type Ge substrate 10 is employed as the support substrate in each of the aforementioned first to third embodiments, the present invention is not restricted to this but a GaP substrate, an Si substrate, a GaAs substrate or the like may be employed.

While the n-type GaN substrate 50 is employed as the growth substrate in each of the aforementioned first to fourth embodiments, the present invention is not restricted to this but a sapphire substrate or the like may be employed.

While the ridge 20c is formed on the substantially central portion of the semiconductor laser device portion 20 in the direction A in the aforementioned first embodiment, the present invention is not restricted to this but the ridge 20c may be formed on a position deviating from the central portion of the semiconductor laser device portion 20 in the direction A by a prescribed distance.

While the region 22b of the n-type cladding layer 22 is formed on the portion approaching the central portion by substantially equal distances from the both side ends of the region 22a in the direction A in the aforementioned first embodiment, the present invention is not restricted to this but the region 22b of the n-type cladding layer 22 may be formed on a portion approaching the central portion by different distances from the both side ends of the region 22a in the direction A. Also according to the structure in this modification, the step portions 22c are formed by the regions 22a and 22b, and hence a crack can be inhibited from being caused in the n-type cladding layer 22 (region 22b) in the vicinity of the active layer 23.

While the semiconductor laser device portion 20 is formed with the two or three ridges 20c in each of the aforementioned second and third embodiments, the present invention is not restricted to this but more than three waveguides may be formed.

While the two or three regions 22b are formed on the single region 22a of the n-type cladding layer 22 and the active layer 23 and the p-type cladding layer 24 are formed on each of the regions 22b, thereby the single semiconductor laser device portion is provided with the plurality of laser beam emitting portions in each of the aforementioned second and third embodiments, the present invention is not restricted to this but more than three regions 22b may be formed on the single region 22a of the n-type cladding layer 22 thereby forming a semiconductor laser device portion having more than three laser beam emitting portions.

While the three-wavelength semiconductor laser device 400 is formed by the blue semiconductor laser device portion 450 and the two-wavelength semiconductor laser device 410 constituted by the red semiconductor laser device portion 420 and the infrared semiconductor laser device portion 430 in the aforementioned fourth embodiment, the present invention is not restricted to this but a red semiconductor laser device may be bonded to a two-wavelength semiconductor laser device constituted by a green semiconductor laser device and a blue semiconductor laser device thereby forming a three-wavelength semiconductor laser device emitting an RBG laser beam.

In each of the aforementioned first to third embodiments, a selective growth mask of SiO₂ or the like may be employed as a layer for separation.

1. A semiconductor laser device, comprising a first semiconductor device portion and a support substrate bonded to said first semiconductor device portion, wherein
said first semiconductor device portion comprises:
a cavity;
a first conductivity type first cladding layer having a first region of a first width in a second direction intersecting with a first direction in which said cavity extends and a second region of a second width smaller than said first width in said second direction, formed on said first region; and
a first active layer and a second conductivity type second cladding layer formed on said second region of said first cladding layer.

2. The semiconductor laser device according to claim 1, wherein
said second cladding layer has a planar portion and a projecting portion having a third width smaller than said second width, formed on said planar portion.

3. The semiconductor laser device according to claim 2, wherein
a plurality of said projecting portions are formed, and
each of portions of said first active layer corresponding to said plurality of projecting portions becomes a waveguide of said first semiconductor device portion.

4. The semiconductor laser device according to claim 1, wherein
a step portion is formed on said first cladding layer by said first region and said second region, and
said step portion is formed to extend along said first direction.

5. The semiconductor laser device according to claim 4, wherein
said second region is formed on a region excluding both ends of said first region.

6. The semiconductor laser device according to claim 1, wherein
said second region has a fourth width smaller than said second width in the vicinity of a facet of said cavity.

7. The semiconductor laser device according to claim 1, wherein
widths of said first active layer and said second cladding layer in said second direction are the same as said second width.

8. The semiconductor laser device according to claim 1, wherein
a plurality of said second regions are formed.

9. The semiconductor laser device according to any one of claim 1, wherein
a width of said first region is smaller than a width of said support substrate.

10. The semiconductor laser device according to claim 1, wherein
said first semiconductor device portion further includes an insulating film covering a side surface of said first region.

11. The semiconductor laser device according to claim 1, wherein
a second semiconductor device portion having a second active layer is formed in said support substrate.

12. The semiconductor laser device according to claim 1, wherein
a side of said second cladding layer of said first semiconductor device portion is bonded to said support substrate.

13. The semiconductor laser device according to claim 1, wherein
said first semiconductor device portion and said support substrate are bonded to each other through a fusion layer.

14. A method of manufacturing a semiconductor laser device, comprising steps of:
growing a first conductivity type first cladding layer, an active layer and a second conductivity type second cladding layer on a growth substrate;
forming said first cladding layer to have a first region of a first width and a second region of a second width smaller than said first width, formed on said first region; and
bonding a support substrate to a side of said second cladding layer on said growth substrate.

15. The method of manufacturing a semiconductor laser device according to claim 14, further comprising a step of removing said growth substrate.

16. The method of manufacturing a semiconductor laser device according to claim 14, wherein
said growth substrate has a defect concentration region in a striped shape.

17. The method of manufacturing a semiconductor laser device according to claim 16, further comprising a step of removing said first cladding layer, said active layer and said second cladding layer in at least a part of said defect concentration region.

18. The method of manufacturing a semiconductor laser device according to claim 14, further comprising a step of forming a planar portion and a projecting portion having a third width smaller than said second width, formed on said planar portion, in said second cladding layer after said step of forming said first cladding layer to have said first region and said second region.

19. The method of manufacturing a semiconductor laser device according to claim 18, wherein
said step of forming said projecting portion in said second cladding layer includes a step of forming a plurality of said projecting portions in said second cladding layer.

20. The method of manufacturing a semiconductor laser device according to claim 14, wherein
said step of growing said first cladding layer includes a step of growing said first cladding layer through a layer for separation on said growth substrate.
